(19) United States
(12) Patent Application Publication
(10) Pub. No.: US 2022/0138540 A1
(43) Pub. Date: May 5, 2022

(54) INTEGRATED CIRCUIT WITH A CONFIGURABLE NEUROMORPHIC NEURON APPARATUS FOR ARTIFICIAL NEURAL NETWORKS

(71) Applicant: International Business Machines Corporation, Armonk, NY (US)

(72) Inventors: Angeliki Pantazi, Thalwil (CH); Milos Stanisavljevic, Adliswil (CH); Stanislaw Andrzej Wozniak, Kilchberg ZH (CH); Thomas Bohnstingl, Thalwil (CH); Evangelos Stavros Eleftheriou, Rueschlikon (CH)

(21) Appl. No.: 17/085,173

(22) Filed: Oct. 30, 2020

(51) Int. Cl. G06N 3/063; G06N 3/04; G11C 13/00

(52) U.S. Cl. CPC G06N 3/063; G11C 13/0002; G06N 3/04

(57) ABSTRACT

The present disclosure relates to an integrated circuit comprising a first neuromorphic neuron apparatus. The first neuromorphic neuron apparatus comprises an input and an accumulation block having a state variable for performing an inference task on the basis of input data comprising a temporal sequence. The first neuromorphic neuron apparatus may be switchable in a first mode and in a second mode. The accumulation block may be configured to perform an adjustment of the state variable using a current input signal of the first neuromorphic neuron apparatus and a decay function indicative of a decay behavior of the apparatus. The state variable may be dependent on previously received one or more input signals of the first neuromorphic neuron apparatus.

### BACKGROUND

The invention relates in general to the field of neural network systems and, in particular, to an integrated circuit comprising a neuromorphic neuron apparatus.

Neural networks are a computational model used in artificial intelligence systems. Neural networks are based on multiple artificial neurons. Each artificial neuron is connected with one or more other neurons, and links can enhance or inhibit the activation state of adjoining neurons. However, there is a need for improved hardware systems to execute such neural networks. In order to improve a performance of a neural network hardware system, such a hardware may be designed as a neuromorphic hardware.

### STATEMENT REGARDING PRIOR DISCLOSURES BY THE INVENTOR OR A JOINT INVENTOR

The following disclosure(s) are submitted under 35 U.S.C. 102(b)(1)(A):

DISCLOSURE(S): Deep Learning Incorporating Biologically Inspired Neural Dynamics and in-memory computer, Stanislaw Wozniak, Angeliki Pantazi, Thomas Bohnstingl & Evangelos Eleftheriou, Jun. 15, 2020, pages 325-336.

### SUMMARY

Various embodiments provide an integrated circuit, a multi-core-chip architecture, and method as described by the subject matter of the independent claims. Advantageous embodiments are described in the dependent claims. Embodiments of the present invention can be freely combined with each other if they are not mutually exclusive.

In one aspect, the invention relates to an integrated circuit comprising a first neuromorphic neuron apparatus, the first neuromorphic neuron apparatus comprising an input and an accumulation block having a state variable for performing an inference task on the basis of input data comprising a temporal sequence. The first neuromorphic neuron apparatus may be switchable in a first mode and in a second mode. The accumulation block may be configured to perform an adjustment of the state variable using a current input signal of the first neuromorphic neuron apparatus and a decay function indicative of a decay behavior of the apparatus. The state variable may be dependent on previously received one or more input signals of the first neuromorphic neuron apparatus. The first neuromorphic neuron apparatus may be configured to receive the current input signal via the input. Furthermore, the first neuromorphic neuron apparatus may be configured to generate an intermediate value as a function of the state variable if the first neuromorphic neuron apparatus is switched in the first mode. Furthermore, the first neuromorphic neuron apparatus may be configured to generate the intermediate value as a function of the current input signal and independently of the state variable if the first neuromorphic neuron apparatus is switched in the second mode. Furthermore, the first neuromorphic neuron apparatus may be configured to generate an output value as a function of the intermediate value.

In another aspect, the invention relates to a multi-core-chip architecture, the architecture comprising integrated circuits as cores, each integrated circuit comprising a first neuromorphic neuron apparatus, the first neuromorphic neuron apparatus comprising an input and an accumulation block having a state variable for performing an inference task on the basis of input data comprising a temporal sequence, the first neuromorphic neuron apparatus being switchable in a first mode and in a second mode.

The accumulation block may be configured to perform an adjustment of the state variable using a current input signal of the first neuromorphic neuron apparatus and a decay function indicative of a decay behavior of the apparatus. The state variable may be dependent on previously received one or more input signals of the first neuromorphic neuron apparatus. The first neuromorphic neuron apparatus may be configured to receive the current input signal via the input. Furthermore, the first neuromorphic neuron apparatus may be configured to generate an intermediate value as a function of the state variable if the first neuromorphic neuron apparatus is switched in the first mode. Furthermore, the first neuromorphic neuron apparatus may be configured to generate the intermediate value as a function of the current input signal and independently of the state variable if the first neuromorphic neuron apparatus is switched in the second mode. Furthermore, the first neuromorphic neuron apparatus may be configured to generate an output value as a function of the intermediate value.

In another aspect, the invention relates to a method for generating an output value of an integrated circuit, the integrated circuit comprising a first neuromorphic neuron apparatus, the first neuromorphic neuron apparatus comprising an input and an accumulation block having a state variable for performing an inference task on the basis of input data comprising a temporal sequence, the first neuromorphic neuron apparatus being switchable in a first mode and in a second mode. The method comprises performing an adjustment of the state variable using a current input signal of the first neuromorphic neuron apparatus and a decay function indicative of a decay behavior of the apparatus, the state variable being dependent on previously received one or more input signals of the first neuromorphic neuron apparatus; receiving the current input signal via the input; generating an intermediate value as a function of the state variable if the first neuromorphic neuron apparatus is switched in the first mode or generating the intermediate value as a function of the current input signal and independently of the state variable if the first neuromorphic neuron apparatus is switched in the second mode; generating the output value of the integrated circuit as a function of the intermediate value.

In another aspect, the invention relates to a computer program product comprising a computer-readable storage medium having computer-readable program code embodied therewith, the computer-readable program code configured to implement all of steps of the method.

### BRIEF DESCRIPTION OF THE SEVERAL VIEWS OF THE DRAWINGS

In the following embodiments of the invention are explained in greater detail, by way of example only, making reference to the drawings in which:

FIG. 1 illustrates an integrated circuit with a neuromorphic neuron apparatus in accordance with the present subject matter.

FIG. 2 illustrates an input data flow of the integrated circuit.

FIG. 3 illustrates a neural network to be simulated by means of the integrated circuit in accordance with the present subject matter.

FIG. 4 illustrates a decay function block of the integrated circuit.

FIG. 5 illustrates an accumulation block and an output generation block of the neuromorphic neuron apparatus.

FIG. 6 illustrates a further integrated circuit with a neuromorphic neuron apparatus in accordance with the present subject matter.

FIG. 7 illustrates a crossbar array of memristors.

FIG. 8 illustrates the integrated circuit of FIG. 6 being coupled to a bus system.

FIG. 9 illustrates a further integrated circuit with a neuromorphic neuron apparatus in accordance with the present subject matter.

FIG. 10 illustrates a multi-core-chip architecture in accordance with the present subject matter.

FIG. 11 is a flowchart of a method for generating an output value of the integrated circuit of FIG. 6.

FIG. 12 illustrates a chart comprising an initialization function for setting up a memory element of the crossbar array shown in FIG. 7.

FIG. 13 illustrates a time-dependent initialization function.

### DETAILED DESCRIPTION

The descriptions of the various embodiments of the present invention will be presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The first neuromorphic neuron apparatus (NNA) may be used to simulate one neuron or more neurons of an artificial neural network. As well, the first NNA may be considered as one neuron of the artificial neural network. If the first NNA is switched in the first mode, the first NNA may be used for performing an inference task on the basis of input data comprising a temporal sequence. The inference task may be realized by computing repeatedly the adjustment of the state variable using the decay function by means of the accumulation block. If the first NNA is switched in the second mode, the first NNA may be used for performing a further inference task on the basis of further input data which does not comprise a temporal sequence. The further inference task may be realized by computing the intermediate value independently of the state variable. In this case the first NNA may be considered as a non-stateful neuron of the artificial neural network. A non-stateful neuron may be a neuron used in a common multi-layer-perceptron (MLP) without recurrent connections. A non-stateful neuron may also be a neuron used in a common recurrent neural network (RNN) for processing input with a temporal sequence. In this case some inputs of the neuron may constitute inputs from external recurrent connections, i.e. operating from outside of the first NNA.

The input data comprising the temporal sequence may refer to a voice record and the inference task may refer to a speech recognition. The further input data may be in the form of a picture and the further inference task may be performing an object recognition.

The first NNA may be switched in the first or second mode in an initialization procedure of the integrated circuit (IC). After the initialization procedure, the IC may be used, for example, for a training of the neural network and/or for the inference task or the further inference task respectively without reswitching the mode of the first NNA. In another example, the first NNA may be switched from the first mode into the second mode or vice versa after the initialization procedure of the IC. This may be useful for applications involving adjustments of an architecture of the neural network. The adjustments may comprise a change of the type of a single neuron or more neurons of a layer of the neural network. The layer refers to a layer comprising the first NNA. Hence, the presented IC may alleviate a fast design of the neural network and may especially alleviate a rapid design change and advantageously an automatic design change of the neural network.

A switching of the first NNA from the first into the second mode or vice versa may be performed as a function of a value of a parameter indicative of a performance of the neural network. The parameter may indicate an energy consumption or a training performance of the neural network. Hence, the presented IC may alleviate a faster learning of the neural network or a saving of energy when training the neural network or using the neural network for inference tasks.

The state variable may be maintained by, for example, exchanging the state variable through internal recurrent connections of the first NNA or by using other means such as memories such as memristive devices e.g. phase-change memory or other memory technologies. In the case of memristive devices, a value of the state variable may be represented by the device conductance. The first NNA being switched in the first mode may enable an accurate and efficient processing of the input data comprising the temporal sequence. For example, streams of this input data may directly be feed into the first NNA and preferably independently be processed by the first NNA. This may render the first NNA applicable to tasks such as unsegmented, connected handwriting recognition or speech recognition if it is switched in the first mode.

According to one embodiment, the integrated circuit further comprises a first assembly of memory elements. The first assembly of memory elements comprises input connections for applying corresponding voltages to the respective input connections to generate single electric currents in the respective memory elements. In on example, the voltages may be applied in the form of voltage pulses with a constant voltage but with different lengths or number of the pulses within a time interval for performing a pulse width modulation. In a further example, the voltages may be applied comprising different voltage values of at least two of the voltages. The voltages may be applied by means of a voltage source or a current source. The first assembly further comprises at least one output connection for outputting an output electric current. The memory elements are connected to each other such that the output electric current is a sum of the single electric currents. The output connection of the first assembly may be coupled to the input of the first neuromorphic neuron apparatus. The integrated circuit may be configured to generate the current input signal on the basis of the output electric current.

According to one embodiment, the memory elements may be resistive memory elements, also referred to as memristors. The resistive memory elements may be phase change memory (PCM), metal-oxide resistive RAM, conductive bridge RAM or magnetic RAM elements. The resistive memory elements may have each a conductance G which may be changeable by applying a programming voltage or current to the respective resistive memory element (RME). A single weight of the network may be represented by the conductance G of one or more RMEs. The single weight of the network may be indicative of a strength of a connection between the first NNA and a further neuron being arranged in a further layer of the network. The further layer may be arranged between the layer comprising the first NNA and an input layer of the network. In one example, a higher value of the weight may indicate a stronger connection between the first NNA and the further neuron.

According to one embodiment, the memory elements may be charge-based memory devices, such as static random-access memory (SRAM) elements.

The memory elements may be connected to each other such that at least each of the memory elements may have an electric link another one of the memory elements. The electric link may be direct or indirect. The indirect link may comprise a resistor. In this case at least two of the memory elements may be connected to each other via the resistor.

As the memory elements are connected to each other such that the output electric current is a sum of the single electric currents, the output electric current may be regarded as a result of a scalar product of a first vector and a second vector. Herein, the first vector may comprise values of the corresponding voltages as entries. The second vector may comprise entries, wherein each entry may be a value stored in one or more of the memory elements, for example in the form of a value of a conductance of one or more RMEs. Hence, the first assembly enables a computation of the scalar product on a hardware level by an addition of the single electric currents to the sum. This embodiment represents a very fast way to obtain the result of the scalar product, for example faster than a computation of the scalar product performed in a conventional CPU.

The fast computation of the scalar product may be useful when running the first NNA in the first mode. This may be due to the following reason. Compared to the first NNA being run in the second mode and being clocked with a second time step size, the first NNA being run in the first mode may require being clocked with a first time step size, wherein the second time step size may be higher than the first time step size. Therefore, the first NNA being run in the first mode may require a higher frequency of computation of the scalar product. This may be adequate in order to resolve temporal effects of the input data comprising the temporal sequence. The fast computation of the scalar product by means of the first assembly may reduce latency and thus may enable to use the first NNA being switched in the first mode for certain real world applications. As a result, the first assembly may alleviate a real application of the IC with the first NNA being switchable between the first and the second mode, especially considering the IC applied to real world applications.

According to one embodiment, the IC may further comprise a comparison circuit. The comparison circuit may be configured to compare the intermediate value with a threshold value if the first NNA is switched in the first mode. According to this embodiment, the first NNA may be configured to set the output value equal to one if the intermediate value is greater than the threshold value and to set the output value equal to zero if the intermediate value is less than or equal to the threshold value. The threshold value may represent a threshold of a potential of the first NNA, which, in this case may be considered as a spiking neuron. The comparison circuit may contribute to a spiking characteristic of the first NNA if the first NNA is switched in the first mode. In this case, the first NNA may be considered as a spiking neuron of the network.

The present integrated circuit (IC) comprising the comparison circuit may provide an IC being configured to simulate or represent a neuron or a layer of neurons of the neural network, wherein the network may be a spiking neural network (SNN) or a layer of the network may be a spiking layer, in case the first NNA is switched in the first mode. The spiking layer may be a layer of neurons, wherein all neurons of that layer may be spiking neurons.

Using the SNN or the spiking layer may be advantageous as it may enable a sparse communication in the time domain within the network. This may reduce heat generation and energy consumption of the IC.

Using the spiking neural network may be advantageous compared to other type of networks, such as an MLP or RNN, as it may have relaxed requirements for a required memory and for the required communication of neuronal outputs in a multi-layer architecture. For example, the memory contents may be represented with low precision or even binary values may be sufficient. A spike of the first NNA may be in one example represented as a binary value of one. This may allow an area-efficient and flexible implementation of the memory. This may also allow to exploit novel storage technologies (e.g. RMEs).

According to one embodiment, the integrated circuit may further comprise an analog digital converter (ADC). The output connection of the first assembly of the memory elements may be coupled to the input of the first neuromorphic neuron apparatus via the ADC. The output connection of the first assembly may be coupled to an input connection of the ADC and an output connection of the ADC may be coupled to the input of the first neuromorphic neuron apparatus. The ADC may be configured to convert the output electric current into the current input signal, wherein the current input signal is a digital signal. The current input signal being digital may have the advantage that a logic to realize the first NNA may be digital. This may reduce costs of producing the IC. Generally, the first NNA may be realized by analog elements as well.

According to one embodiment, the integrated circuit may further comprise further assemblies of memory elements. In one embodiment, the memory elements of the further assemblies may be RMEs. The further assemblies of the memory elements may each be connected to the input connections of the first assembly for applying the corresponding voltages to the memory elements of each of the further assemblies to generate respective further single electric currents in the respective memory elements of each of the further assemblies. Each of the further assemblies may comprise a respective output connection for outputting a respective further output electric current. The memory elements of each of the further assemblies may be connected to each other such that the respective further output electric current is a respective sum of the respective further single electric currents in the memory elements of the respective assembly. The integrated circuit may be configured to generate corresponding further current input signals on the basis of the respective further output electric currents. The IC may further be configured to generate further output values each on the basis of the respective further current input signal by means of the first NNA or further neuromorphic neuron apparatuses of the IC.

A conductance G of one or more RMEs of the further assemblies may represent a single weight of the network. The single weight of the network may be indicative of a strength of a connection between a further NNA and a second further neuron being arranged in the further layer of the network mentioned above.

As the memory elements of each of the further assemblies are connected to each other such that the respective further output electric current is the respective sum of the respective further single electric currents, the respective further output electric current may be regarded as a respective result of a respective scalar product of the first vector and a respective further second vector. The respective second further vector may comprise entries, wherein each entry may be a value stored in one or more of the memory elements of the respective further assembly, for example in the form of a value of a conductance of one or more RMEs of the respective further assembly. Hence, the further assemblies each may enable a computation of the respective scalar product on the hardware level each by an addition of the respective further single electric currents to the respective sum. Furthermore, the respective further output electric currents together may be considered as a result vector. The result vector may comprise entries, wherein each entry may represent a value of the respective further output electric current.

Therefore, this embodiment represents a very fast way to obtain a result of a matrix vector multiplication, the matrix comprising the respective further second vectors and the second vector as columns and the vector being the first vector.

In case, the conductance G of the RMEs of the further assemblies may represent respective single weights of the network, the entries of the result vector may each be indicative to the current input signal or to the respective further current input signal of a neuron of the layer comprising the first NNA. The entries of the first vector may each be indicative to a current output signal of a neuron of the further layer, which is arranged between the layer and the input layer. Hence, the matrix vector multiplication may be considered as a propagation of the output signals of the neurons of the further layer to respective inputs of neurons of the layer comprising the first NNA. As the matrix vector multiplication may be performed on the hardware level via using the RMEs this multiplication may be performed faster than on a conventional CPU. This may allow to use the first NNA being switched in the first mode and being clocked with the first time step size in order to better process temporal information of the input data comprising the temporal sequence in the context of a layer to layer propagation in the network. This may allow to create and use deep neuronal networks with hundreds of hidden layers and to perform inference tasks with input data sets comprising many temporal sequences.

According to one embodiment, the integrated circuit may further comprise the analog digital converter (ADC), a first memory and a sequential circuit, the analog digital converter being configured to convert the output electric current into the current input signal and the further output electric currents into the respective further current input signals, the first memory being configured to store the current input signal and the further current input signals, the sequential circuit being configured to send the current input signal and the further current input signals sequentially to the input of the first neuromorphic neuron apparatus.

According to this embodiment, the integrated circuit may be configured to generate the further output values each on the basis of the respective further current input signal by means of the first NNA. This may be accomplished by the first NNA generating the further output values sequentially on the basis of the respective further current input signals. The sending of the current input signals may be realized in the following way. The sequential circuit may read the current input signal and the further current input signals sequentially from the first memory and forward these values sequentially to the input of the first NNA. This embodiment may enable performing the layer to layer propagation by using just a single artificial neuron circuit, such as the first NNA. This is advantageous as a number of neurons of the layer does not need to be known a priori in order to realize a simulation of the network on the hardware level.

According to one embodiment, the integrated circuit may further comprise the further neuromorphic neuron apparatuses. The further neuromorphic neuron apparatuses may each comprise an input and an accumulation block having a state variable for performing the inference task on the basis of the input data comprising the temporal sequence. Each further neuromorphic neuron apparatus may be switchable in a first and a second mode. Each of the respective further output connections of the further assemblies may be coupled, i.e. electronically coupled, to one of the inputs of the further neuromorphic neuron apparatuses. The accumulation block of the respective further neuromorphic neuron apparatus may be configured to perform an adjustment of the state variable of the respective accumulation block using the further current input signal of the respective further neuromorphic neuron apparatus and a decay function indicative of a decay behavior of the respective apparatus. The state variable of the respective accumulation block may be dependent on previously received one or more input signals of the respective further neuromorphic neuron apparatus.

The respective further neuromorphic neuron apparatus may be configured to receive the further current input signal of the respective further neuromorphic neuron apparatus via an input of the respective further neuromorphic neuron apparatus.

Furthermore, the respective further neuromorphic neuron apparatus may be configured to generate an intermediate value of the respective further neuromorphic neuron apparatus as a function of the state variable of the respective accumulation block if the respective further neuromorphic neuron apparatus is switched in the first mode.

Furthermore, the respective further neuromorphic neuron apparatus may be configured to generate the intermediate value of the respective further neuromorphic neuron apparatus as a function of the further current input signal of the respective further neuromorphic neuron apparatus and independently of the state variable of the respective accumulation block if the respective further neuromorphic neuron apparatus is switched in the second mode.

Furthermore, the respective further neuromorphic neuron apparatus may be configured to generate the respective further output value as a function of the intermediate value of the respective neuromorphic neuron apparatus. This embodiment may enable to generate the output value and the further output values in parallel by means of the first NNA and the further NNAs allowing a significant speed-up of the layer to layer propagation. Furthermore, according to this embodiment, the ADC may forward the current input signal and the further current input signals directly to the input of the first NNA and the further NNAs respectively without saving these signals in the first memory. The sequential circuit may also not be needed in this embodiment.

According to one embodiment, the memory elements of the first assembly and the memory elements of the further assemblies may be arranged in rows and columns. The memory elements may each represent one of the entries of the matrix. The entries of the matrix may represent a respective weight of a connection between two neurons of the artificial neural network. The layer of the artificial neuronal network may be simulated by means of the first NNA. In one example, the layer may comprise the first NNA and the further NNAs. An arrangement of the RMEs in rows and columns may simplify the design and production of the first assembly and the further assemblies.

According to one embodiment, the integrated circuit may further comprise a first switchable circuit. The first switchable circuit may be configured to run in a first mode or in a second mode. The first switchable circuit may be configured to generate the intermediate value as a function of the state variable if the first switchable circuit is switched in the first mode. Furthermore, the first switchable circuit may be configured to generate the intermediate value as a function of the current input signal and independently of the state variable if the first switchable circuit is switched in the second mode. According to this embodiment only one single circuit may be needed to generate the intermediate value. This may reduce a number of circuits of the IC. Parts of the first switchable circuit may be commonly used when the first switchable circuit is switched in the first mode and in the second mode. Such a part of the first switchable circuit may be a logic realizing a fused multiplication and addition.

According to one embodiment, the first switchable circuit may be configured to generate the intermediate value as a function of the current input signal and parameter values derived from a batch normalization algorithm of a training data set for training the first neuromorphic neuron apparatus if the first switchable circuit is switched in the second mode. According to this embodiment, the parameter values derived from the batch normalization algorithm may be input values of the logic realizing the fused multiplication and addition. The batch normalization may alleviate a faster training of the network. Performing the inference task with the network trained using the batch normalization may require converting the current input value and the further current input values by multiplying them with the parameter values derived from the batch normalization algorithm. Thus, this embodiment may enable to use the batch normalization in a training and an inference task of the network.

According to one embodiment, the integrated circuit may further comprise a second switchable circuit and a configuration circuit. The second switchable circuit may be configured to run in a first mode or in a second mode and to generate the output value according to a first activation function on the basis of the intermediate value if the second switchable circuit is switched in the first mode. Furthermore, the second switchable circuit may be configured to generate the output value according to a second activation function on the basis of the intermediate value if the second switchable circuit is switched in the second mode. The configuration circuit may be configured to switch the first switchable circuit and the second switchable circuit in the first mode or the second mode. In one example, the configuration circuit may be configured to switch the first switchable circuit and the second switchable circuit simultaneously in the first mode or the second mode. The first activation function is different from the second activation function. This may enhance a flexibility of the IC to different real world applications. The first activation function may be a rectified linear function, a sigmoid function or a hyperbolic tangent. As well, the second activation function may be a rectified linear function, a sigmoid function or a hyperbolic tangent.

According to one embodiment, the integrated circuit may further comprise a further configuration circuit. The further configuration circuit or the configuration circuit mentioned above may be configured to switch the first neuromorphic neuron apparatus and the respective further neuromorphic neuron apparatuses simultaneously in the first mode or in the second mode. This embodiment may enable a fast and synchronous switching from the first mode into the second mode of all the NNAs and vice versa.

According to one embodiment, the integrated circuit may further comprise a rectified linear unit. The rectified linear unit may be configured to generate a further intermediate value as a function of the intermediate value independently if the first neuromorphic neuron apparatus is switched in the first mode or if the first neuromorphic neuron apparatus is switched in the second mode. The first neuromorphic neuron apparatus may be configured to generate the output value on the basis of the further intermediate value. The rectified linear unit (ReLU) may be part of the first NNA. The ReLU may enable a fast learning in the training of the network.

According to one embodiment, the comparison circuit may be configured to compare the further intermediate value with the threshold value if the first neuromorphic neuron apparatus is switched in the first mode. According to this embodiment the first neuromorphic neuron apparatus may be configured to set the output value equal to the further intermediate value if the further intermediate value is greater than the threshold value and to set the output value equal to zero if the further intermediate value is less than or equal to zero. This embodiment may combine the advantages of the ReLU and the first NNA being a spiking neuron.

According to one embodiment, the integrated circuit may further comprise an input conversion circuit. The input conversion circuit may be configured to scale the current input signal using a scaling. The scaling may depend on a range of output values of the analog digital converter and may be independent from a mode of the first neuromorphic neuron apparatus. That means that the scaling may be the same, independent it the first NNA is switched in the first or in the second mode. Therefore, the input conversion circuit may be used in both modes of the first NNA and thereby reducing the number required circuits in the IC.

According to one embodiment, the first neuromorphic neuron apparatus may be configured to generate the output value such that a range of admissible values of the output value is independent of a mode of the first neuromorphic neuron apparatus. That means that the range of the admissible values of the output value is the same, the first NNA being switched in the first or in the second mode. This embodiment may enhance a compatibility of different layers of the network to each other.

According to one embodiment, each memory element may comprise a respective changeable conductance, wherein the respective conductance may be in a respective drifted state. The respective memory element may be configured for setting the respective conductance to a respective initial state. In addition, the respective memory element may comprise a respective drift of the respective conductance from the respective initial state to the respective drifted state. The respective initial state of the respective conductance may be computable by means of a respective initialization function. The respective initialization function may be dependent on a respective target state of the respective conductance and the respective target state of the respective conductance may be approximately equal to the respective drifted state of the respective conductance.

The term “drift” as used herein describes a change of a value of the conductance over time such as a decay of the conductance over time. The term “drifted state” as used herein describes a changed state of the conductance compared to the initial state. Between a point of time when the conductance is in the initial state and a further point of time when the conductance is in the drifted state time has passed. Furthermore, in the drifted state of the conductance of the resistive memory element the change of the conductance over time may be less than a change of the conductance over time in the initial state of the conductance. For this reason, an information which may be represented by an actual value of the conductance of the resistive memory element may be kept over time with a higher precision if the conductance is in the drifted state. In one example, the change of the conductance over time in the drifted state of the conductance may be less than ten percent compared to a change of the conductance over time in the initial state of the conductance. In another example, the change of the conductance over time in the drifted state of the conductance may be less than five, or according to a further example less than one, percent compared to the change of the conductance over time in the initial state of the conductance.

Hence, after setting the conductance to an initial value, a change over time of the conductance reduces as time passes. This effect was observed to be dependent of the initial value of the conductance in experiments. This embodiment provides a storage device using the resistive memory elements with a higher precision compared to a standard use case. The standard use case may comprise programming the conductance of the resistive memory elements to the initial state and use the resistive memory elements directly afterwards. This advantage may be used to generate the above mentioned single electric currents. The output electric current, which may be generated as a sum of the single electric currents, may be generated with a higher precision. Hence, the respective resistive memory elements with their respective conductance being in the respective drifted state may be used to perform a more accurate addition on a hardware level.

The initial state or value of the conductance may be computed by means of the initialization function using a computer, for example a look-up table. In another example, the conductance may be computed by means of the initialization function in a manual manner.

According to one embodiment, the accumulation block may comprise a memory element, in the following also referred to as accumulation block memory element (ABME). The ABME may comprise a changeable physical quantity for storing the state variable. The physical quantity may be in a drifted state, the ABME being configured for setting the physical quantity to an initial state, wherein the ABME comprises a drift of the physical quantity from the initial state to the drifted state, wherein the initial state of the physical quantity is computable by means of a further initialization function, wherein the further initialization function is dependent on a target state of the physical quantity and the target state of the physical quantity is approximately equal to the drifted state of the physical quantity and is dependent on the state variable.

The term “drifted state” as used herein describes a change of a value of the physical quantity over time such as a decay of the physical quantity over time. The term “drifted state” as used herein describes a changed state of the physical quantity compared to the initial state. Between a point of time when the physical quantity is in the initial state and a further point of time when the physical quantity is in the drifted state time has passed. Furthermore, in the drifted state of the physical quantity of the ABME the change of the physical quantity over time may be less than a change of the physical quantity over time in the initial state of the physical quantity. For this reason, an information which may be represented by an actual value of the physical quantity of the ABME may be kept over time with a higher precision if the physical quantity is in the drifted state. In one example, the change of the physical quantity over time in the drifted state of the physical quantity may be less than ten percent compared to a change of the physical quantity over time in the initial state of the physical quantity. In another example, the change of the physical quantity over time in the drifted state of the physical quantity may be less than five, or according to a further example less than one, percent compared to the change of the physical quantity over time in the initial state of the physical quantity. The physical quantity may be a conductance of the ABME.

The ABME may be a resistive memory element. Hence, the ABME may be a phase change memory (PCM), metal-oxide resistive RAM, conductive bridge RAM or magnetic RAM element. The ABME may have a conductance G which may be changeable by applying a programming voltage or current to the ABME. A value of the state variable may be represented by the conductance G of the ABME.

The initial state or value of the physical quantity of the ABME may be computed by means of the further initialization function using a computer, for example a further look-up table. In another example, the conductance may be computed by means of the further initialization function in a manual manner.

According to one embodiment of the multi-core-chip architecture, each integrated circuit may further comprise a respective first assembly of memory elements. The memory elements of the first assembly of each integrated circuit may be RMEs. The respective first assembly of memory elements of the respective IC may comprise input connections for applying corresponding voltages to the respective input connections to generate single electric currents in the respective RMEs of the first assembly of the respective IC. Furthermore, the respective first assembly of the RMEs of the respective IC may comprise at least one output connection for outputting a corresponding output electric current of the first assembly of the respective IC. The RMEs of the first assembly of the respective IC may be connected to each other such that the respective output electric current is a sum of the single electric currents. The output connection of the respective first assembly may be coupled to the input of the first neuromorphic neuron apparatus of the respective integrated circuit. Each integrated circuit may be configured to generate the current input signal of the first neuromorphic neuron apparatus of the respective integrated circuit on the basis of the respective output electric current. According to this embodiment at least two of the integrated circuits may be connected to each other to simulate a neural network comprising at least two hidden layers. This embodiment may enable to perform fast computations of a scalar product as mentioned above with respect to different cores, i.e. different ICs of the multi-core-chip architecture. Analogously, each IC of the multi-core-chip architecture may also comprise further assemblies of RMEs like the presented IC comprises to realize fast vector matrix multiplications on each core of the multi-core-chip architecture.

One of the ICs of the multi-core-chip architecture, in the following referred to as the first IC, may simulate a first hidden layer of the network. Another one the ICs of the multi-core-chip architecture, in the following referred to as the second IC, may simulate a second hidden layer of the network.

According to one embodiment of the multi-core-chip architecture, the first neuromorphic neuron apparatus of at least one of the integrated circuits, e.g. the first IC, may be switched in the first mode and the first neuromorphic neuron apparatus of at least one of the other integrated circuits, e.g. the second IC, may be switched in the second mode. For example, the first NNA of the first IC may be switched in the first mode and the first NNA of the second IC may be switched in the second mode. In this case, the first hidden layer may be arranged between the second hidden layer and the input layer of the network. For example, the first layer may be used to perform a speech recognition and the second layer may perform a classification task on the basis of a performed speech recognition by the first layer. In this example, temporal input data may be proceeded by spiking neurons of the first layer and the classification tasks may performed using simple neurons of the second layer. The simple neurons may be neurons known from MLPs and may not account for temporal effects.

According to one embodiment of the multi-core-chip architecture, the integrated circuits of the multi-core-chip architecture may be controlled by a control circuit. The control circuit may comprise a timer to synchronize the integrated circuits. This may enable a propagation of signals from the first IC to the second IC without generating bottlenecks. Bottlenecks may occur if an NNA of the second layer may wait for its input signal while other NNAs of the second layer already received their input signals.

According to one embodiment of the multi-core-chip architecture, the first integrated circuit may be clocked with the first time step size and the first neuromorphic neuron apparatus of the first integrated circuit may be switched in the first mode. Furthermore, in this embodiment, the second integrated circuit may be clocked with the second time step size and the first neuromorphic neuron apparatus of the second integrated circuit may be switched in the second mode, the second time step size being an integer multiple of the first time step size. The second time step size being an integer multiple of the first time step size may enable to synchronize the first IC with the second IC and therefore may enable the propagation of the signals from the first IC to the second IC without generating bottlenecks.

According to one embodiment of the method for computing the output value of the integrated circuit, the method may further comprise generating the current input signal by means of an output electric current of a first assembly of memory elements, the first assembly of memory elements comprising input connections. The method may further comprise applying corresponding voltages to the respective input connections to generate single electric currents in the respective memory elements. The method may further comprise generating the output electric current as a sum of the single electric currents. This embodiment may enable a fast computation of the scalar product of the first vector and the second vector. The memory elements of the first assembly may be RMEs.

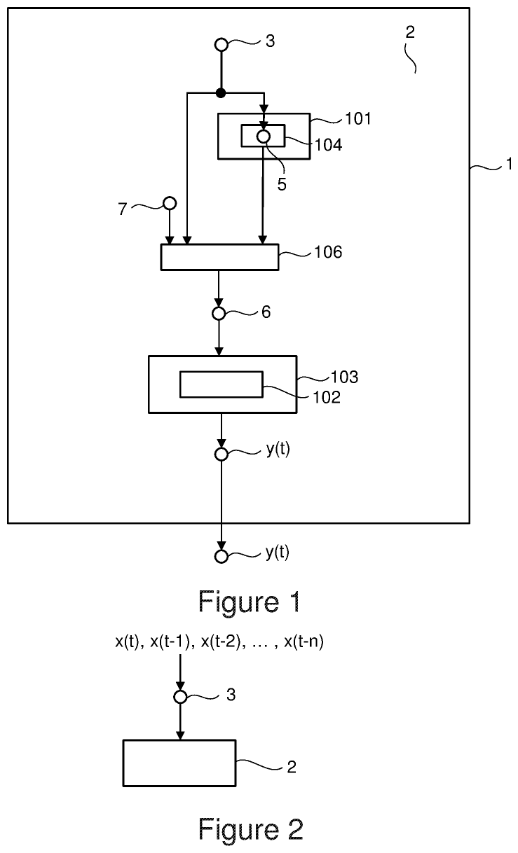

FIG. 1 illustrates an integrated circuit 1 in accordance with an example of the present subject matter. The integrated circuit 1 may be implemented in the form of analog or digital CMOS circuits. The integrated circuit 1 may comprise a first neuromorphic neuron apparatus 2. The first neuromorphic neuron apparatus 2 (NNA 2) may comprise an input 3 and an accumulation block 101 having a state variable 5 for performing an inference task on the basis of input data comprising a temporal sequence. The first NNA 2 may be switchable in a first mode and in a second mode. The accumulation block 101 may be configured to perform an adjustment of the state variable 5 using a current input signal of the first NNA 2 and a decay function indicative of a decay behavior of the apparatus. The state variable 5 may be dependent on previously received one or more input signals of the first NNA 2. The first NNA 2 may be configured to receive the current input signal via the input 3.

Furthermore, the first NNA 2 may be configured to generate an intermediate value 6 as a function of the state variable 5 if the first NNA 2 is switched in the first mode. Furthermore, the first NNA 2 may be configured to generate the intermediate value 6 as a function of the current input signal and independently of the state variable 5 if the first NNA 2 is switched in the second mode. Furthermore, the first NNA 2 may be configured to generate an output value as a function of the intermediate value 6. In one simple example, the first NNA 2 may set the output value equal to the intermediate value 6. According to another further simple example, the first NNA 2 may set the intermediate value 6 equal to the state variable 5 if the first NNA 2 is switched in the first mode.

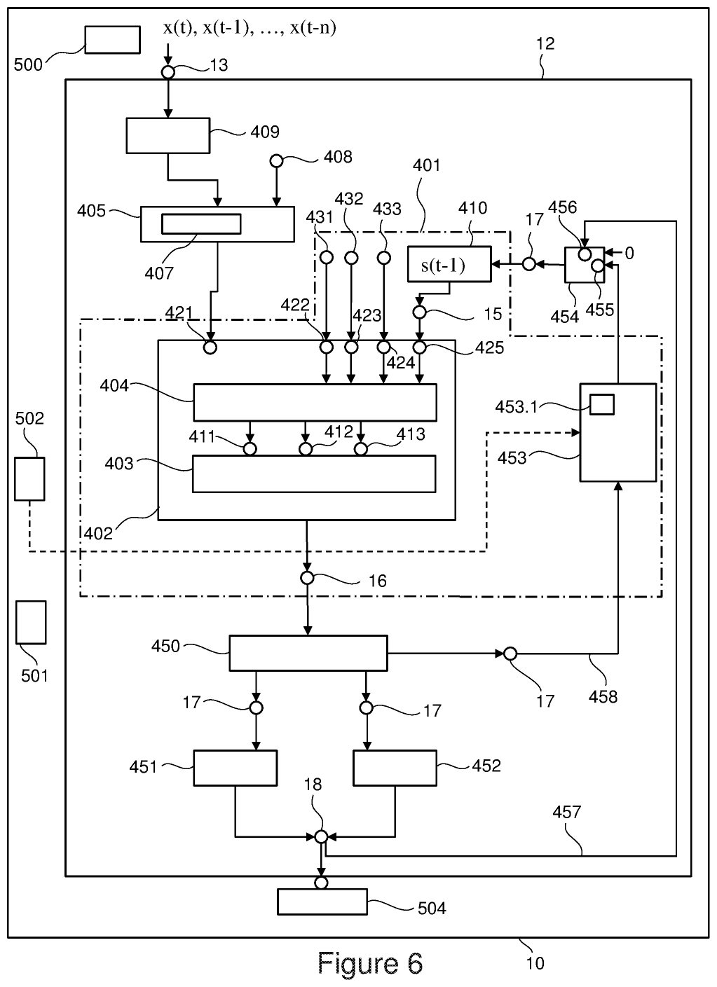

FIG. 6 illustrates a further integrated circuit 10 (IC 10) in accordance with an example of the present subject matter. The integrated circuit 10 may be implemented in the form of CMOS circuits. The CMOS circuits may comprise digital and/or analog circuits. The integrated circuit 10 may comprise a first neuromorphic neuron apparatus 12. The first neuromorphic neuron apparatus 12 (NNA 12) may comprise an input 13 and an accumulation block 401 having a state variable 15 for performing an inference task on the basis of input data comprising a temporal sequence. The first NNA 12 may be switchable in a first mode and in a second mode. The accumulation block 401 may be configured to perform an adjustment of the state variable 15 using the current input signal of the first NNA 12 and a decay function indicative of a decay behavior of the apparatus. The state variable 15 may be dependent on previously received one or more input signals of the first NNA 12. The first NNA 12 may be configured to receive the current input signal via the input 13.

Furthermore, the first NNA 12 may be configured to generate an intermediate value 16 as a function of the state variable 15 if the first NNA 12 is switched in the first mode. Furthermore, the first NNA 12 may be configured to generate the intermediate value 16 as a function of the current input signal and independently of the state variable 15 if the first NNA 12 is switched in the second mode. Furthermore, the first NNA 12 may be configured to generate an output value 18 of the first NNA 12 as a function of the intermediate value 16. In one simple example, the first NNA 12 may set the output value 18 equal to the intermediate value 16. According to another further simple example, the first NNA 12 may set the intermediate value 16 equal to the state variable 15 if the first NNA 12 is switched in the first mode.

The first NNA 2, 12 may be configured to receive a stream of input signals x(t−n) . . . x(t−3), x(t−2), x(t−1), x(t) as shown in FIG. 2. These input signals may constitute a time series. The current input signal may be the signal x(t). The previously received one or more input signals may be the signals x(t−n) . . . x(t−3), x(t−2), x(t−1). Each signal of the input signals may correspond to a value, e.g. a floating-point number. The input signals may be electrical currents if the first NNA 2, 12 is implemented as an analog circuit. The input signals may be binary-coded numbers if the first NNA 2, 12 is implemented in the form of a digital circuit.

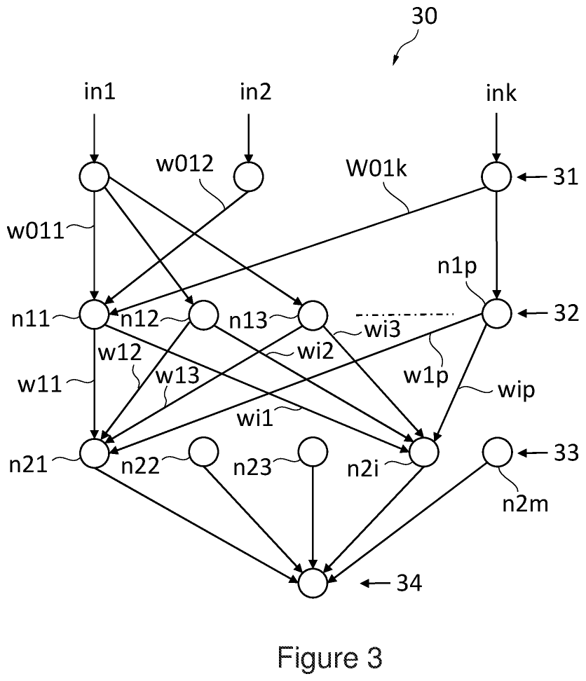

FIG. 3 illustrates a neural network 30. The neural network 30 may comprise an input layer 31 comprising k inputs, e.g. input in1, in2, . . . ink. Furthermore, the neural network 30 may comprise a first hidden layer 32 comprising p neurons, e.g. neuron ni1, n12, n13 . . . nip. Furthermore, the neural network 30 may comprise a second hidden layer 33 comprising m neurons, e.g. neuron n21, n22, n23 . . . n2m. The first NNA 2, 12 may simulate one of the neurons of an actual layer of the network, wherein the first NNA 2, 12 may receive output values of neurons of a previous layer of the network 30. The previous layer may be the first hidden layer 32. The actual layer may be the second hidden layer 33.

The neural network 30 may be configured to process input signals of the neural network 30, such as input signals in1(t), in2(t), . . . , ink(t). For example, each of the signals in1(t−n) . . . , in1(t−1), in1(t), in2(t−n) . . . , in2(t−1), in2(t), ink(t−n) . . . , ink(t−1), ink(t) may be indicative of a respective pixel of an image that may be inputted at a respective time step t−n, . . . t−1, t at the corresponding inputs in1, in2, . . . , ink of the neural network 30. In the following the input signals of the neural network 30 are referred to as input signals of the neural network 30 and the input signals of the first NNA 2, 12 are referred to as input signals.

Each signal of the input signals x(t−n) . . . x(t−3), x(t−2), x(t−1), x(t) may be generated by the IC 1, 10 such that these input signals may each be equal to a scalar product of a first vector and a second vector. Entries of the first vector may represent each an output value of one of the neurons, e.g. the neurons n11, n12, n13 . . . nip, of a previous layer of the neural network 30, e.g. of the first hidden layer 32, at a respective time step t−n, . . . , t−3, t−2, t−1, t. These output values may be floating-point numbers and may be referred to as out11(t−n) . . . out11 (t−3), out11 (t−2), out11 (t−1), out11 (t) as the output values of the first neuron ni1 of the previous layer, as out12(t−n) . . . out12 (t−3), out12 (t−2), out12 (t−1), out12 (t) as the output values of the second neuron n12 of the previous layer, as out13(t−n) . . . out13 (t−3), out13 (t−2), out13 (t−1), out13 (t) as the output values of the third neuron n13 of the previous layer and as out1p(t−n) . . . out1p (t−3), out1p (t−2), out1p (t−1), out1p (t) as the output values of the p-th neuron nip of the previous layer at the respective time step t−n, . . . , t−3, t−2, t−1, t.

Entries of the second vector may represent each a value of a weight, e.g. w11, w12, w13, . . . , w1p, indicative of a strength of a connection between the neuron the first NNA 2, 12 may simulate and a corresponding neuron of the previous layer, e.g. the neuron n11, n12, n13, . . . , nip. Analogously, if the first NNA 2, 12 may simulate neuron n2i of the actual layer, the entries of the second vector may be each a value of a weight wi1, wi2, wi3, . . . , wip.

In one example, the first NNA 2, 12 may simulate a first neuron of the actual layer, e.g. neuron n21, and after that may simulate a second neuron of the actual layer, e.g. neuron n22, and so forth and may simulate an m-th neuron of the actual layer, e.g. neuron n2m.

If the first NNA 2, 12 may simulate the first neuron n21 of the second hidden layer 33, the current input signal may be x(t)=w11*out11 (t)+w12*out12 (t)+w13*out13 (t)+ . . . +wip*out1p (t). Accordingly, one of the previously received input signals x(t−n) may be x(t−n)=w11*out11 (t−n)+w12*out12 (t−n)+w13*out13 (t−n)+ . . . +wip*out1p (t−n). Of course, one of the output values of the neurons of the previous layer may be equal to zero. This may occur frequently, in case, the neurons of the previous layer are spiking neurons.

According to another example, the first NNA 2, 12 may simulate one of the neurons of the first hidden layer 32, e.g. neuron n11. In this case, the current input signal may be x(t)=w011*in1 (t)+w012*in2 (t)+w013*in3 (t)+ . . . +w01k*ink (t). Accordingly, one of the previously received input signals x(t−n) may be x(t−n)=w011*in1 (t−n)+w012*in2 (t−n)+w013*in3 (t−n)+ . . . +w01k*ink (t−n).

In one example, the first NNA 2 may further comprise an output generation block 103. In order to generate the output value of the first NNA 2 in accordance with the present subject matter, the first NNA 2 involves the state variable 5, in the following also referred to as time dependent state variable s(t), s(t−1), . . . , s(t−n). The state variable s(t) may represent a membrane potential at the time step (t) that may be used to define the output value at that time step. The state variable s(t) may indicate a current activation level of the first NNA 2. Incoming spikes in the form of single products w11*out11 (t), w12*out12 (t), w13*out13 (t), . . . or w1p*out1p (t) may increase this activation level, and then either decaying over time or firing a spike. This may happen independent of the first NNA 2 being switched in the first or the second mode. The single products may be generated by incoming electrical currents or digital values at the input 3.

For example, for each received input signal x(t−n) . . . x(t−3), x(t−2), x(t−1), x(t), a respective state variable s(t−n) . . . s(t−3), s(t−2), s(t−1), s(t) may be computed by the accumulation block 101. The output generation block 103 may comprise an activation function 102 to compute the output value of the first NNA 2 at time step (t), in the following also referred to as y(t). The computed s(t) may be provided or output by the accumulation block 101 as the intermediate value 6 to the output generation block 103 if the first NNA 2 is switched in the first mode. According to one embodiment, the current input signal x(t) may be passed to the output generation block 103 if the first NNA 2 is switched in the second mode.

In one embodiment, the first NNA 2 may comprise a first switchable circuit 106. The first switchable circuit 106 may be configured to run in a first mode or in a second mode. The first switchable circuit 106 may be configured to generate the intermediate value 6 as a function of the state variable s(t) if the first switchable circuit is switched in the first mode. Furthermore, the first switchable circuit 106 may be configured to generate the intermediate value 6 as a function of the current input signal x(t) and independently of the state variable if the first switchable circuit is switched in the second mode.

In one example, the first switchable circuit 106 may be configured to generate the intermediate value 6 as a function of the current input signal x(t) and parameter values 7 derived from a batch normalization algorithm of a training data set for training the first neuromorphic neuron apparatus if the first switchable circuit is switched in the second mode.

The output generation block 103 may generate the output value y(t) depending on the value of the state variable s(t) if the first NNA 2 is switched in the first mode. The output generation block 103 may use the activation function 102 for generating the output value y(t) depending on the value of the state variable s(t) if the first NNA 2 is switched in the first mode. The activation function 102 may be a step function, a sigmoid function or a rectified linear activation function. In one example, the first NNA 2 may be biased because it may have an additional input with constant value b, the constant value b (bias value) may be taken into account. For example, the bias value b may be used for determining the output value y(t) as follows y(t)=h(s(t)+b) if the first NNA 2 is switched in the first mode, where h may be the activation function 102. This may enable an improved performance of the first NNA 2.

Thus, for each received signal x(t) of the stream x(t−n) . . . x(t−3), x(t−2), x(t−1), x(t), the first NNA 2 may be configured to provide, in accordance with the present subject matter, the state variable s(t) using the accumulation block 101 and an output value y(t) using the output generation block 103 if the first NNA 2 is switched in the first mode. The state variable s(t) may be considered as the intermediate value 6 in this example. The intermediate value 6, in this example the state variable s(t), may be computed as a function of the current input signal x(t) and the state variable s(t−1). If the value b is equal to zero, the output value y(t) may be equal to the state variable s(t) if the first NNA 2 is switched in the first mode.

For computing the state variable s(t) by the accumulation block 101, an initialization of the first NNA 2 may be performed. The initialization may be performed such that before receiving any input signal at the input 3 of the first NNA 2, the state variable s(0) and the output variable y(0) may be initialized to respective predefined values. This may enable an implementation based on feedbacks from previous states of the first NNA 2 as follows.

The accumulation block 101 may be configured to compute the state variable s(t) taking into account a previous value of the state variable e.g. s(t−1) and a previous output value e.g. y(t−1). The previous values of the state variable and the output value s(t−1) and y(t−1) may be the values determined by the first NNA 2 for a previously received signal x(t−1) as described herein. For example, the accumulation block 101 may be configured to compute the state variable s(t) for the received signal x(t) as follows: s(t)=g(x(t)+s(t−1)⊙(1−y(t−1))), where g may be a further activation function 104. The further activation function 104 may be implemented in the accumulation block 101. For the very first received signal x(t−n), initialized values s(t−n)=s(0) and y(t−n)=y(0) may be used to compute the state variable s(t−n+1). The formula s(t−1)⊙(1−y(t−1)) is an adjustment of the state variable 5.

The received signal x(t) may induce a current into the first NNA 2. Depending on the current level, the state variable 5 may decay or fall depending on a time constant τ of the first NNA 2. This decay may for example be taken into account by the accumulation block 101 for computing the adjustment of the state variable 5. For that, the adjustment of s(t−1) may be provided as follows: l(τ)⊙s(t−1)⊙(1−y(t−1)), where l(τ) is a correction function that takes into account the decay behavior of the state variable s(t) with the time constant c. Thus, the accumulation block 101 may be configured to compute s(t) as follows: s(t)=g(x(t)+l(τ)⊙s(t−1)⊙(1−y(t−1))), where g is the further activation function 104. The values of l(τ) may for example be stored in a memory (not shown) of the first NNA 2. For example, the correction function may be defined as follows

$$l ( τ ) = ( 1 - \frac{Δ T}{τ} ) ,$$

where ΔT is the sampling time. The sampling time may be the time difference between the time steps (t) and (t−1) or (t−i) and (t−i−1).

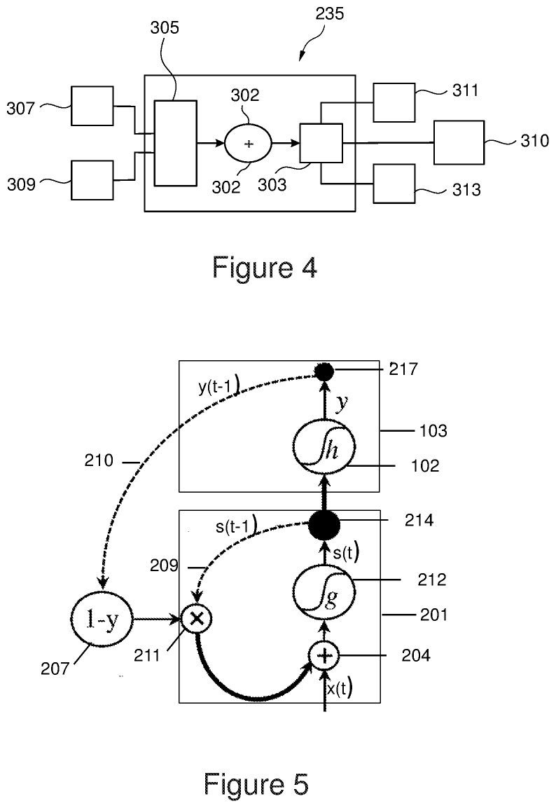

According to one embodiment, the accumulation block 101 may comprise a first decay function block (DFB) 235 as illustrated in FIG. 4 for performing the adjustment of the state variable 5. The first DFB 235 may realize the decay function. The first DFB 235 may receive the input signals via the input 3 and processes the input signals. For example, for each received input signal, the first DFB 235 may sum a corresponding value of the received input signal up to the state variable 5. The state variable 5 may be considered as a membrane state variable, e.g. as a membrane potential variable, of the first DFB 235. In one example, the first DFB 235 may compute a new value of the state variable s(t) at each new time step as a function of the current input signal x(t) and the of one or more previously received input signals, such as x(t−1), . . . , x(t−n).

The first DFB 235 comprises a selection unit 305, an adder 302, a synapse unit 309, an output 310 and a memory 303. The memory 303 may store a given number n+1 of the input signals. For example, the memory 303 may store the latest n+1 input signals. The input signals may be stored in the memory 303 according to the FIFO (first in first out) principle. Hence, if the current input signal x(t) may be received by the first DFB 235 the input signal which was received at first compared to all input signals, e.g. x(t−n−1), may be deleted in the memory 303.

The input signals may pass through the synapse unit 309. The selection unit 305 may select for each received input signal x(t−n) . . . x(t−3), x(t−2), x(t−1), x(t), in the following referred to as xᵢ, a weight value (or modulating term) αᵢ that corresponds to an arrival time of the received input signal xᵢ. The selection unit 305 may select the corresponding weight value of the respective input signal xᵢ such that the more recent received input signals are assigned to the weight values having a higher value. By that the decay function may be realized.

The selection unit may perform a multiplication of the respective input signal xᵢ and its corresponding selected weight value αᵢ. The selection unit 305 may output the result of each multiplication. As for each new time step, the weight values may be assigned anew to each of the stored input values, the selection unit 305 may perform n+1 multiplications at each time step.

The adder 302 may be configured to add the single results of each multiplication xᵢ*α₁ to generate a sum of these multiplications. This sum may be equal to the current value of the state variable. The current value of the state variable may be s(t).

The first DFB 235 may further comprise a comparator 313. The comparator 313 may be configured to determine whether the current value of state variable 5 is greater than or equal to a threshold value. The threshold value may, for example, be received from a unit (not shown) of the first DFB 235 or may be stored in the comparator 313. The first DFB 235 may be configured to spike if the current value of the state variable 5 is greater than or equal to the threshold value. The first DFB 235 may generate a spike by outputting an output signal at the output 310. The output signal may be an electric impulse, in case the IC 1 is implemented in the form of an analog circuit. The output signal may be a binary value, e.g. “1”, or a digital number, in case the IC 1 is implemented in the form of a digital circuit.

The first DFB 235 may further comprise a reset unit 311. The reset unit 311 may be configured to set the current value of the state variable 5 to a reset value if the first DFB 235 spikes. The reset value may be stored in the first DFB 235. For example, the reset value may be equal to zero.

The first DFB 235 may further comprise a weight unit 307 configured to provide the weight values al to the selection unit 305. The weight unit 307 may, for example, comprise a lookup table comprising the weight values al in association with the arrival time. In one example, the weight unit 307 may provide the weight values al such that they decrease in an exponential or logarithmic way with respect to a time difference. The selection unit 305 may be configured to calculate a respective time difference for each received input signal. The selection unit 305 may comprise a timer for computing the respective time differences.

The output signal of the first DFB 235 may be the intermediate value 6. In this example, the intermediate value 6 may be generated as a function of the current value of the state variable 5 and passed to the output generation block 103.

FIG. 5 illustrates another example implementation of an accumulation block 201 of the first NNA 2 in accordance with the present subject matter. FIG. 5 shows the status of the accumulation block 201 after receiving the signal x(t).

The accumulation block 201 comprises an adder circuit 204, multiplication circuit 211, and activation circuit 212. The multiplication circuit 211 may for example be a reset gate. The accumulation block 201 may be configured to output at the branching point 214, the computed state variable 5 in parallel to the output generation block 103 and to the multiplication logic 211. The connection 209 between the branching point 214 and the multiplication logic 211 is shown as a dashed line to indicate that the connection 209 is with a time-lag. That is, at the time step (t) the first NNA 2 is processing the received input signal x(t) to generate corresponding s(t) and y(t), the connection 209 may transmit a value of a previous state of the state variable 5, i.e. the value of s(t−1).

According to this example, the output generation block 103 may generate the output value y(t) as a function of the state variable s(t) if the first NNA 2 is switched in the first mode. The output generation block 103 may provide or output the output value y(t) of the first NNA 2 at a branching point 217 in parallel to an output of the first NNA 2, and to a reset module 207 of the first NNA 2. The reset module 207 may be configured to generate a reset signal from the received output value and provide the reset signal to the multiplication logic 211. For example, for a given output value y(t−1), the reset module may generate a reset signal indicative of a value 1−y(t−1). In this example, the output value may be a binary value, e.g. “0” or “1”. The connection 210 is shown as a dashed line to indicate that the connection 210 is with a time-lag. That is, at the time the first NNA 2 is processing a received signal x(t) to generate corresponding s(t) and y(t), the connection 210 may transmit a previous output value y(t−1). The connections 209 and 210 may enable a feedback capability to the first NNA 2. In particular, the connection 209 may be a self-looping connection within the accumulation block and the connection 210 may activate a gating connection for performing the state reset.

Upon receiving the state variable value s(t−1) and the output value y(t−1), the multiplication logic 211 may be configured to compute an adjustment as follows: l(τ)⊙s(t−1)⊙(1−y(t−1)). The adjustment computed by the multiplication circuit 211 is output and fed to the adder circuit 204. The adder circuit 204 may be configured to receive the adjustment from the multiplication circuit 211 and the input signal x(t) from the input 3. The adder circuit 204 may further be configured to perform the sum of the received adjustment and the signal as follows: x(t)+l(τ)⊙s(t−1)⊙(1−y(t−1)). This sum is provided or output by the adder circuit 204 to the activation circuit 212. The activation circuit 212 may be configured to receive the computed sum from the adder circuit 204. The activation circuit 212 may be configured to apply its activation function on the computed sum in order to compute the state variable 5 as follows: s(t)=g(x(t)+l(τ)⊙s(t−1)⊙(1−y(t−1))). The resulting state variable s(t) may be output in parallel to the output generation block 103 and to the multiplication circuit 211 (the outputting to the multiplication circuit 211 may be useful for a next received signal x(t+1)). The generated output value y(t) may be output to the reset module 207 for usage for a next received signal x(t+1).

Referring back to FIG. 6, the accumulation block 401 comprises the state variable 15, in the following also referred to as time dependent state variable 15 s(t), s(t−1), . . . , s(t−n). The state variable 15 s(t) may represent a membrane potential at the time step (t) that may be used to define the output value 18 of the first NNA 12 at that time step (t). The state variable 15 s(t) may indicate a current activation level of the first NNA 12. Incoming spikes in the form of single products w11*out11 (t), w12*out12 (t), w13*out13 (t), . . . or w1p*out1p (t) may increase this activation level, and then either decaying over time or firing a spike. According to this example, this may happen only, if the first NNA 2 is switched in the first mode. The single products may be generated by incoming electrical currents or digital values at the input 13, depending on whether the IC 10 is implemented in the form of analog or digital circuits.

For example, for each received input signal x(t−n) . . . x(t−3), x(t−2), x(t−1), x(t), a respective state variable 15 s(t−n) . . . s(t−3), s(t−2), s(t−1), s(t) may be computed by the accumulation block 401. According this example, the IC 10 may comprise a first switchable circuit 402. The first switchable circuit 402 may be configured to generate the intermediate value 16 as a function of the state variable 15 s(t−1) of a previous time step and the current input value x(t) if the first neuromorphic neuron apparatus is switched in the first mode. Furthermore, the first switchable circuit 402 may be configured to generate the intermediate value 16 as a function of the current input signal x(t) and independently of the state variable 15 if the first neuromorphic neuron apparatus is switched in the second mode.

According to the example shown in FIG. 6, the first switchable circuit 402 may comprise a fused multiplication and addition circuit 403 (FMAC 403). Furthermore, the FMAC 403 may comprise a first input 411, a second input 412 and a third input 413. The FMAC 403 may be configured to compute an output value of the FMAC 403 (output_FMAC) dependent on a value applied to the first input 411 (input_1_FMAC), a value applied to the second input 412 (input_2_FMAC) and on a value applied to the third input 413 (input_3_FMAC) according to the following equation: output_FMAC=input_1_FMAC+input_2_FMAC*input_3_FMAC. Using a fused multiplication and addition circuit is advantageous as such a type of circuit is a standard circuit and may be producible at very low costs and area footprint. As well such a standard circuit may be optimized with respect to heat production, fatigue and generation of overvoltages. This holds for a digital and an analog implementation of the FMAC 403 on the IC 10.

The first switchable circuit 402 may comprise a switch 404, a first input 421, a second input 422, a third input 423, a fourth input 424 and fifth input 425.

Furthermore, the first NNA 12 may comprise an input conversion circuit 405, the input conversion circuit being configured to scale the current input signal x(t) using a scaling. The scaling may dependent on a range of possible output values of an analog digital converter (ADC) 500 and may be independent from a mode of the first NNA 12, i.e. if it is switched in the first or in the second mode. The input conversion circuit 405 may comprise a fused multiplication and addition circuit 407 to perform the scaling of the current input signal x(t) dependent on scaling values 408 defining the range of the ADC 500. The scaling values may be sent from the ADC 500 to the first NNA 12 or may be provided as a fixed value in a memory of the IC 10. The NNA 12 may also comprise a further input conversion circuit 409. The further input conversion circuit 409 may be configured to convert an integer value of the current input signal x(t) into a float value of the current input signal x(t).

The first NNA 12 may be configured to transmit the converted and scaled input signal x(t) to the first input 421 of the first switchable circuit 402, independently of the mode of the first NNA 12. Hence, the converted and scaled input signal x(t) may be applied to the first input 425.

In one example, a first batch normalization parameter 431 may be applied to the second input 422 and a second batch normalization parameter 432 may be applied to the third input 423. The IC 10 may be configured to transmit the first batch normalization parameter 431 to the second input 422 and to transmit the second batch normalization parameter 432 to the third input 423. The first and second batch normalization parameter 431, 432 may be obtained from a batch normalization approach using training datasets to train the neural network 30.

In one example, a decay factor 433 (dec_fac) may be applied to the fourth input 424. The decay factor 433 may be constant in one example. In another example, the decay factor 433 may vary over time. The decay factor 433 may change from time step to time step as a function of a clock frequency the IC 10 is clocked with. For example, the decay factor may vary over time according to the correction function

$$l ( τ ) = ( 1 - \frac{Δ T}{τ} ) .$$

A time step size ΔT may be equal to a time interval between two executions of the IC 10. Dependent on the clock frequency, the time step size ΔT may change.

In one example, a value of the state variable 15 s(t−1) of the previous time step may be applied to the fifth input 425. The IC 10 may be configured to transmit the value of the state variable 15 s(t−1) of the previous time step from a first memory element 410 of the first NNA 12 to the fifth input 425.

The IC 10 may further comprise a configuration circuit 501. The configuration circuit 501 may be configured to switch the first NNA 12 in the first mode or in the second mode.

In one example, the configuration circuit 501 may be configured to switch the switch 404 in a first mode. The switch 404 may connect the first input 421 of the switchable circuit 402 to the first input 411 of the FMAC 403, the fourth input 424 of the switchable circuit 402 to the second input 412 of the FMAC 403 and the fifth input 425 of the switchable circuit 402 to the third input 413 of the FMAC 403 if the switch 404 is switched in the first mode. Thus, in the first mode of the switch 404, the converted and scaled input signal x(t) may be applied to the first input 411 of the FMAC 403, the decay factor 433 may be applied to the second input 412 of the FMAC 403 and the value of the state variable 15 s(t−1) of the previous time step may be applied to the third input 413 of the FMAC 403.

Thus, the FMAC 403 may generate the output value of the FMAC 403 according to the following equation: output_FMAC=x(t)+dec_fac*s(t−1), if the switch 404 is switched in the first mode.

Furthermore, the configuration circuit 501 may be configured to switch the switch 404 in a second mode. The switch 404 may connect the second input 432 of the switchable circuit 402 to the first input 411 of the FMAC 403, the first input 421 of the switchable circuit 402 to the second input 412 of the FMAC 403 and the third input 433 of the switchable circuit 402 to the third input 413 of the FMAC 403 if the switch 404 is switched in the second mode. Thus, in the second mode of the switch 404, the first batch normalization value 431 (batch1) may be applied to the first input 411 of the FMAC 403, the converted and scaled input signal x(t) may be applied to the second input 412 of the FMAC 403 and the second batch normalization value 432 (batch2) may be applied to the third input 413 of the FMAC 403.

Thus, the FMAC 403 may generate the output value of the FMAC 403 according to the following equation: output_FMAC=batch1+x(t)*batch2, if the switch 404 is switched in the second mode.

The output value of the FMAC 403 may be the intermediate value 16 independent of the mode of the switch 404.

In addition, the IC 10 may comprise an activation unit 450. The activation unit 450 may be configured to apply an activation function such as a sigmoid, hyperbolic tangent, linear or rectified linear function. A particularly beneficial low-complexity circuit implementation of the activation unit 450 may be a rectified linear unit. Therefore, the activation unit 450 may be also referred to as ReLU 450 in the following. The ReLU 450 may be configured to generate a further intermediate value 17 as a function of the intermediate value 16. The ReLU 450 may generate the further intermediate value 17 if the first NNA 12 is switched in the first mode. In another example, the ReLU 450 may generate the further intermediate value 17 independently of the mode of the first NNA 12. The ReLU 450 may generate the further intermediate value 17 such that the further intermediate value 17 is equal to the intermediate value 16 (int_val) if the intermediate value 16 is greater than or equal to zero and such that the further intermediate value 17 is equal to zero if the intermediate value 16 is less than zero.

In one example, the ReLU 450 may be biased because it may have an additional input with constant value c, the constant value c (bias value) may be taken into account. For example, the bias value c may be used for determining the further intermediate value 17 (furth_int_val) as follows furth_int_val=ReLU(int_val+c). This may enable an improved performance of the first NNA 12. In one example, the bias value c may be used for determining the further intermediate value 17 (furth_int_val) as follows furth_int_val=ReLU(int_val+c) only if the first NNA 12 is switched in the first mode.

The first NNA 12 may be configured to generate the output value 18 on the basis of the further intermediate value 17. In one example, the first NNA 12 may generate the output value 18 as an integer value using an output conversion circuit 451 of the IC 10. The output conversion circuit 451 may be configured to convert a floating-point number into an integer value if the first NNA 12 is switched in the second mode.

In addition, the first NNA 12 may generate the output value 18 in the form of a spike. The spike may be produced by means of a comparison circuit 452 of the IC 10. The comparison circuit 452 may be configured to compare the further intermediate value 17 with a threshold value. The comparison circuit may compare the further intermediate value 17 with the threshold value if the first NNA 2 is switched in the first mode. Furthermore, the comparison circuit 452 may be configured to set the output value 18 equal one if the further intermediate value 17 is greater than the threshold value and to set the output value 18 equal to zero if the further intermediate value 17 is less than or equal to the threshold value. Hence, the comparison circuit 452 may contribute to a spiking character of the first NNA 12. In fact, first NNA 12 may be configured to simulate a spiking neuron if the first NNA 12 is switched in the first mode. By that, the output value 18 may be a binary value if the first NNA 12 is switched in the first mode. This may enable a low-power spike-based communication when using the first NNA 12 for simulating the network 30.

The first NNA 12 may output the output value 18 via an output 453 of the first NNA 12, independently of the mode of the first NNA 12. In another example, not shown in FIG. 6, the first NNA 12 may output the output value 18 via a first output of the first NNA 12 if the output value 18 is generated by means of the output conversion circuit 451 and output the output value 18 via a second output of the first NNA 12 if the output value 18 is generated by means of the comparison circuit 452.

The IC 10 may be configured to transmit the further intermediate value 17 from the activation unit 450 to a register 453. The register 453 may be designed as a storage element of the IC 10. The register 453 may be configured to store the further intermediate value 17 in a first register element 453.1 of the register 453.

The IC 10 may be configured to transmit stored content of the one of the register elements of the register 453 to a multiplexer 454 of the IC 10. The multiplexer 454 may be configured to pass through the further intermediate value 17 which may be stored in the first register element 453.1 and may be sent to a first input 455 of the multiplexer 454 to the first memory element 410 via an output of the multiplexer 454 and an input of the first memory element 410.

The multiplexer 454 may be configured to pass through a value from the first input 455 of the multiplexer 454 to the first memory element 410 if a steering signal which may be applied at a second input 456 of the multiplexer 454 is equal to zero. In addition to that, the multiplexer 454 may pass through this value if there is no signal level applied at the second input 456, in one example. The multiplexer 454 may put out a value being equal to zero to the first memory element 410 if a signal level greater than zero is applied at the second input 456. This may happen in case the output value 18 calculated by means of the comparison circuit 452 is greater than zero.

Hence, a first feedback loop 457 of the IC 10 may function together with the multiplexer 454 as reset apparatus for the first memory element 410. A second feedback loop 458 may provide a storage mechanism to store the further intermediate value 17, in this case the current value of the state variable 15 s(t), in the register 453 and to provide the current value of the state variable s(t) to the first memory element 410 in the next time step. The first memory element 410 may be configured to store the current value of the state variable 15 s(t), here in the form of the further intermediate value 17, for a time period being as long as a time step size of the first NNA 12. The first NNA 12 may be clocked with a first time step size. The second feedback loop 458 may be performed at each time step.

The first switchable circuit 402, the register 453 and the first memory element 410 may build together the accumulation block 401 to perform an adjustment of the state variable 15 using the current input signal x(t) and a decay function given by the product dec_fac*s(t−1). As this product may be added to the current input signal x(t) by means of the first switchable circuit 402 an accumulation may be performed at each time step when running the first NNA 12 with the first time step size. As the first switchable circuit 402 may also be used to compute the output value 18 if the first NNA 12 is switched in the second mode, a part of the accumulation block 401 may be used to compute the output value 18 if the first NNA 12 is switched in the second mode. Thus, a number of circuits may be reduced, especially if the output value 18 is calculated dependent on the batch normalization parameters batch1 and batch2.

The accumulation block 401 may comprise a memory element, such as a memory element of the register 453, for example the first register element 453.1, for storing the state variable 15, for example the current value of the state variable 15. The first register element 453.1 may store the current value of the state variable 15 s(t) of an actual time step (t) in the form of the further intermediate value 17 for providing this value at the next time step as mentioned above. The first register element 453.1 may comprise a physical quantity being in a drifted state after a time interval has passed after programming the first register element 453.1. The time interval may be the first time step size. For example, the first register element 453.1 may be a resistive memory element comprising a changeable conductance.

The drifted state of the physical quantity of the first register element 453.1 may be approximately equal to a target state of the physical quantity of the first register element 453.1. In one example, the drifted state of the physical quantity of the first register element 453.1 may deviate from the target state of the physical quantity of the first register element 453.1 less than ten, or in another example less than one, percent.

The physical quantity of the first register element 453.1 may be in a drifted state in the next time step. The target state of the physical quantity of the first register element 453.1 may be the current value of the state variable 15 s(t) of the actual time step (t).

The first register element 453.1 may be configured for setting the physical quantity to an initial state G_{453.1}_{ᵢₙᵢₜ} and to comprise a drift of the physical quantity of the first register element 453.1 from the initial state G_{453.1}_{ᵢₙᵢₜ} to the drifted state with the time interval.

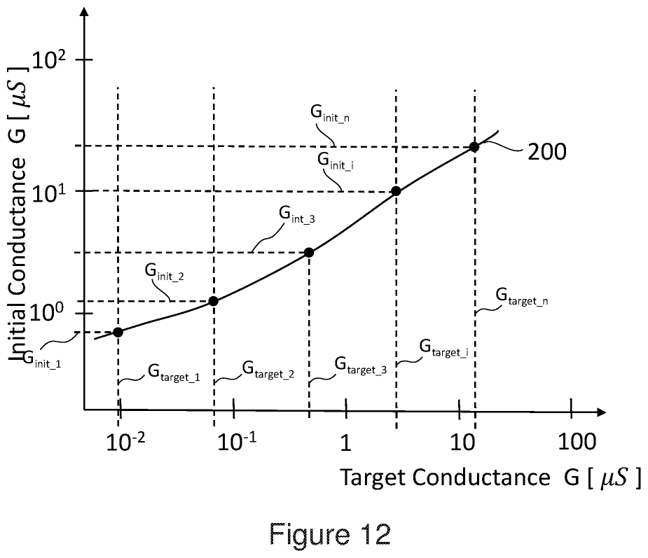

The initial state of the physical quantity G_{453.1}_{ᵢₙᵢₜ} may be computable by a processor by means of an initialization function, for example the initialization function 200 shown in FIG. 12.

The initialization function 200 may map the target state of the conductance G of the first register element 453.1, in the FIG. 12 depicted as G_{target_i}, to the initial value of the conductance G_{453.1}_{ᵢₙᵢₜ} of the first register element 453.1, in the FIG. 12 depicted as G_{init_i}. The initialization function 200 may be a polynomial gained by experiments performed with the first register element 453.1.

The processor may be an external processor or the control unit 502. The processor may store the parameters or coefficients of the initialization function 200 in order to compute the initial state G_{453.1}_{ᵢₙᵢₜ} of the physical quantity of the first register element 453.1 on the basis of the target state of the physical quantity of the first register element 453.1. The first register element 453.1 may be programmed, for example by the control unit 502, at the actual time step such that the physical quantity of the first register element 453.1 may take on the initial state G_{453.1}_{ᵢₙᵢₜ} at the actual time step.

According to one example, the first NNA 12 may be configured to generate the output value 18 such that a range of admissible values of the output value 18 is independent of the mode of the first NNA 12. This may be achieved by a cutting behavior of the activation unit 450 which may cut off a further increase of the output value 18 if the output value 18 is greater than an upper threshold. By that, a first range of the output value 18, which may refer to possible values of the output value 18 if the first NNA 12 is switched in the first mode, may be equal to a second range of the output value 18, which may refer to possible values of the output value 18 if the first NNA 12 is switched in the second mode.

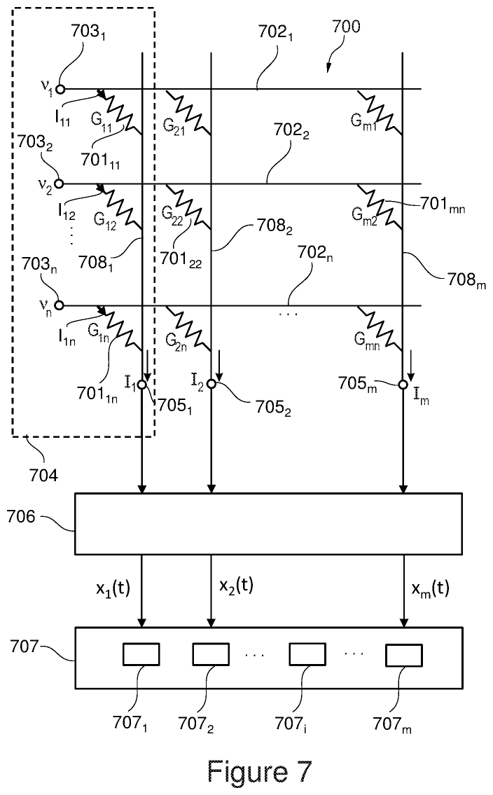

FIG. 7 depicts a crossbar array 700 of memory elements 701. The memory elements 701 may be resistive memory elements (or resistive processing units (RPUs) that may comprise multiple resistive memory elements) and may also be referred to as memristors 701 in the following. The memristors 701 may provide local data storage within the IC 1, 10 for the weights Wᵢⱼ of the neural network 30. FIG. 7 is a two-dimensional (2D) diagram of the crossbar array 700 that may for example perform a matrix-vector multiplication as a function of the weights Wᵢⱼ. The crossbar array 700 may be formed from a set of conductive row wires 702₁, 702₂ . . . 702ₙ and a set of conductive column wires 708₁, 708₂ . . . 708ₘ that may cross the set of the conductive row wires 702₁₋ₙ. Regions where the column wires 708₁₋ₘ may cross the row wires 702₁₋ₙ are shown as intersections in FIG. 7 and may be referred to as intersections in the following. The IC 10 may be designed such that there is no electrical contact between the column wires 708₁₋ₘ and the row wires 702₁₋ₙ at the intersections. For example, the column wires 708₁₋ₘ may be guided above or below the row wires 702₁₋ₙ at the intersections.

In the regions of the intersections the memristors 701 may be arranged with respect to the column wires 708₁₋ₘ and the row wires 702₁₋ₙ such that through each memristor 701ᵢⱼ may flow a single electrical current Iᵢⱼ if respective voltages v₁ . . . vₙ may be applied to input connections 703₁, 703₂ . . . 703ₙ of the crossbar 700 and by that may be applied to the row wires 702₁₋ₙ. The memristors 701 are shown in FIG. 7 as resistive elements each having its own adjustable/updateable resistive conductance, depicted as Gᵢⱼ, respectively where i=1 . . . m, and j=1 . . . n. Each resistive conductance Gᵢⱼ, may correspond to a corresponding weight Wᵢⱼ of the neural network 30.

Each column wire 708₁ may sum the single electrical currents Iᵢ₁, Iᵢ₂ . . . Iᵢₙ generated in the respective memristor 701ᵢ₁, 701ᵢ₂ . . . 701ᵢₙ by applying the respective voltages v₁ . . . vₙ to the corresponding input connections 703₁, 703₂ . . . 703ₙ. For example, as shown in FIG. 7, the current Iᵢ generated by the column wire 708ᵢ is according to the equation Iᵢ=v₁·Gᵢ₁+v₂·Gᵢ₂+v₃·Gᵢ₂+ . . . +vₙ·Gᵢₙ. A first output electric current I₁ generated by the column wire 708₁ is according to the equation I₁=v₁·G₁₁+v₂·G₁₂+v₃·G₁₃+ . . . +vₙ·G₁ₙ. Thus, the array 700 computes the matrix-vector multiplication by multiplying the values stored in the memristors 701 by the row wire inputs, which are defined by voltages v₁₋ₙ. Accordingly, a single multiplication vᵢ·Gᵢⱼ may be performed locally at each memristor 701ᵢⱼ of the array 700 using the memristor 701ᵢⱼ itself plus the relevant row or column wire of the array 700. The currents I₂₋ₙ may be referred to as further output electric currents in the following.

The crossbar array of FIG. 7 may for example enable to compute the multiplication of a vector x with a matrix W. The items Wᵢⱼ of the matrix W may be mapped onto corresponding conductances of the crossbar array as follows:

$${W}_{ij} = \frac{{W}_{max}}{{G}_{max}} {G}_{ij} ,$$

where Gₘₐₓ is given by the conductance range of the crossbar array 700 and Wₘₐₓ is chosen depending on the magnitude of matrix W. The entries of the matrix W may be equal to the weights Wᵢⱼ of the neural network 30 or wij as denoted above. The vector x may correspond to the voltages v₁ . . . vₙ. The IC 1, 10 may be configured to generate the respective voltages v₁ . . . vₙ as a function of the corresponding output values out11 (t), out12 (t), out13 (t) . . . out1p (t) of the neurons of the previous layer, for example the first hidden layer 32.

FIG. 7 illustrates one example of a first assembly 704 of the resistive memory elements 701₁₁, 701₁₂ . . . 701₁ₙ of the IC 10. The first assembly 704 may comprise the input connections 703₁, 703₂ . . . 703ₙ for applying the corresponding voltages v₁ . . . vₙ to the respective input connections 703₁, 703₂ . . . 703ₙ to generate the single electric currents I₁₁, I₁₂ . . . I₁ₙ in the respective resistive memory elements 701₁₁, 701₁₂ . . . 701₁ₙ and a first output connection 705₁ for outputting a first output electric current I₁. The memristors 701₁₁, 701₁₂ . . . 701₁ₙ may be connected to each other such that the first output electric current I₁ is a sum of the single electric currents I₁₁, I₁₂ . . . I₁ₙ. Such a connection between the memory elements 701₁₁, 701₁₂ . . . 701₁ₙ may be provided by the row wires 702₁₋ₙ and the first column wire 708₁. A value of the first output electric current I₁ the may represent a value of a first scalar product to compute an output value of the neural network 30 by means of a propagation of values through the layers of the network 30. The first scalar product may, for example, be equal to or be a multiple or a fraction of x(t)=w11*out11 (t)+w12*out12 (t)+w13*out13 (t)+ . . . +w1p*out1p (t) or x(t)=w011*in1 (t)+w012*in2 (t)+w013*in3 (t)+ . . . +w01k*ink (t). In the former case, the first NNA 2, 12 may simulate the neuron n21, in the latter case the neuron n11. Furthermore, in the former case, the number of row wires n may be equal to p, in the latter case, the number of row wires n may be equal to k.

The first output connection 705₁ of the first assembly 704 may be coupled to the input 13 of the first NNA 12. The IC 10 may be configured to generate the current input signal x(t) on the basis of the first output electric current I₁. In one example, the first NNA 2, 12 may be configured to process the input signal x(t) as an analog signal. In that case, the first output electric current I₁ may be the current input signal x(t).

In another example, the IC 10 may be configured to generate the current input signal x(t) on the basis of the first output electric current I₁ by means of an analog digital converter 706 (ADC 706). In one example, the first NNA 2, 12 may receive the current input signal x(t) only from the first output connection 705₁. This example may refer to an application wherein the first NNA 2, 12 may simulate an output neuron of an output layer 34 of the neural network 30. In this example, the other column wires 708₂₋ₘ may not be needed.

In case, the IC 1, 10 may be used to simulate a layer of the network 30 which comprises more than one neuron, e.g. the first hidden layer 32 or the second hidden layer 33, more than one column wires of the crossbar 700 are needed. A number of the column wires 708₁₋ₘ may be equal to a number of neurons m of that layer, the IC 1, 10 may simulate. A number of the row wires 702₁₋ₙ may be equal to a number of neurons n of the previous layer of the network 30. If the previous layer is the input layer 31, the number of row wires n may be equal to k. If the previous layer is the first hidden layer 32, the number of row wires n may be equal to p.

In the following, it will explained how the IC 10 may simulate a layer of the network 30 which contains more than one neuron, e.g. the second hidden layer 33, by means of the first NNA 2, 12. In this case, the first NNA 1, 12 may not only be used to compute the output value 18 for a single current time step (t) but, in addition to that, further output values. In the following, the output value 18 is referred to as first output value out₁(t) and the further output values as out₂₋ₘ(t). For that purpose, the further output electric currents I₂₋ₘ generated by the column wires 708₁₋ₘ may be used and the IC 1, 10 may comprise a second memory 707.

Furthermore, the ADC 706 may be configured to convert the first output electric current I₁ into the first current input signal x(t) and the further output electric currents I₂₋ₙ into respective further current input signals x₂₋ₘ(t) of the first NNA 2. The further output electric currents I₂₋ₙ may be outputted by further output connections 705₁₋ₘ of the crossbar 700.

The second memory 707 may be configured to store the current input signal x(t), also referred to as xᵢ(t) in the following, and the further current input signals x₂₋ₘ(t). The second memory 707 may comprise m memory elements 707₁₋ₘ and may store in each memory element 707ᵢ one of the current input signals xᵢ(t) and x₂₋ₘ(t).

The IC 1, 10 may be configured to generate the further output values out₂₋ₘ(t) each on the basis of the respective further current input signal x₂₋ₘ(t) by means of the first NNA 2. The applied corresponding voltages v₁ . . . vₙ may correspond to the respective output values of the neurons of the previous layer out11(t), out12(t), . . . , out1p(t) as mentioned above, with n=p in this case.

In one example, one or more of the applied corresponding voltages v₁ . . . vₙ may correspond to an output value of a neuron of the actual layer of a past time step, for example an output value of the second neuron n22 of the second hidden layer 33, which may be referred to as out22(t−1). By that, a recurrent connection of the second hidden layer 33 may be simulated.

In order to generate the further output values out₂₋ₘ(t), the IC 1, 10 may be configured to send sequentially the further current input signals x₂₋ₘ(t) to the input 13 of the first NNA 2, 12 and to control the first NNA 2, 12 to generate each of the further output values out₂₋ₘ(t) on the basis of the respective further current input signal x₂₋ₘ(t) in the same way as the first NNA 2, 12 may generate the first output value out₁(t) on the basis of the first current input signal xᵢ(t) as mentioned above. In doing so, a control unit 502 of the IC 1, 10 may sequentially control a switch of the second memory 707 such that an output connection of the second memory element 707 is connected to one of the memory elements 707₁₋ₘ. The output connection of the second memory element 707 may be connected to the input 13 of the first NNA 2, 12. Upon receiving a value sent by the second memory element 707, i.e. either the first current input signal xᵢ(t) or one of the further current input signals x₂₋ₘ(t), the first NNA 2, 12 may calculate the further intermediate value 17.

The control unit 502 may sequentially control the register 453 such that the further intermediate value 17 may be written in the corresponding register element 453.i, with i corresponding to the index of the current input signal xᵢ(t) if the first NNA 2, 12 is switched in the first mode. As well, the control unit 502 may control the register 453 such that the corresponding register element 453.i may be connected to the input 455 of the multiplexer 454 if the first NNA 2, 12 is switched in the first mode. Upon generating each of the output values out₁₋ₘ(t), the output values out₁₋ₘ(t) may be stored in a third memory 504 of the IC 1, 10.

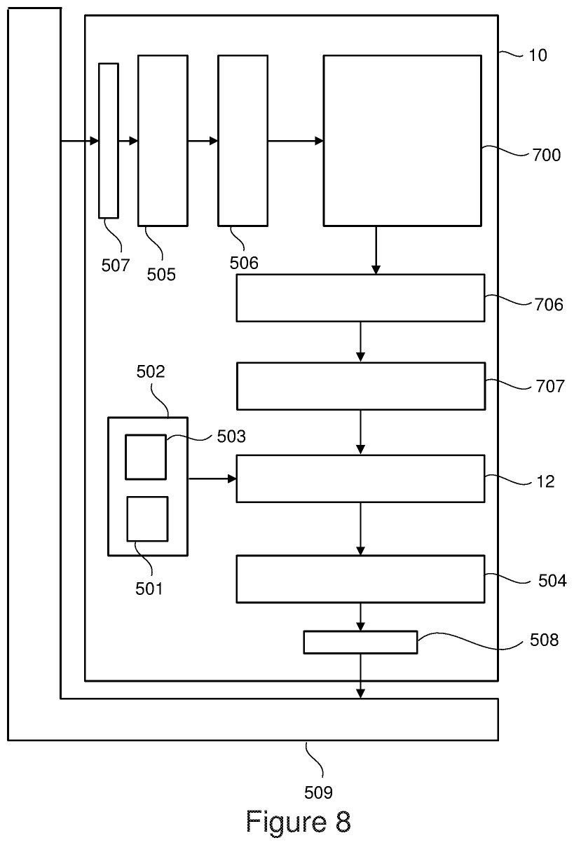

FIG. 8 illustrates the IC 10 comprising the crossbar array 700, the ADC 706, the second memory 707, the first NNA 12, the third memory 504, the configuration circuit 501 and the control unit 502. The configuration circuit 501 and the control unit 502 may be integrated in a configuration and control circuit 503. IC 10 may furthermore comprise a fourth memory 505 for storing incoming signals, for example the output values of the neuron of the previous layer of the network 30, such as out11(t), out12(t), . . . , out1p(t). In addition, the IC 10 may comprise a digital analog converter 506 for converting the digital incoming signals into the corresponding voltages v₁ . . . vₙ. Herein, a pulse-width modulation scheme may be applied to adapt a duration of the corresponding voltages v₁ . . . vₙ to the respective incoming signals. In one example, each value of the corresponding voltages v₁ . . . vₙ may be adapted to the respective incoming signals, with all the corresponding voltages v₁ . . . vₙ comprising the same duration. In one example, the IC 10 may comprise an input communication channel 507 for transmitting the incoming signals from a bus system 509 to the fourth memory 505 and an output communication channel 508 for transmitting the output values out₁₋ₘ(t) to the bus system 509.

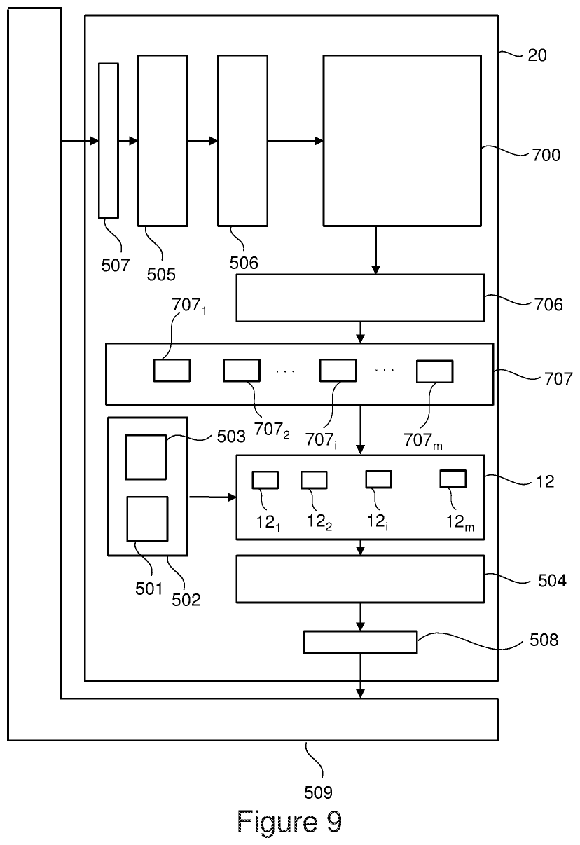

FIG. 9 illustrates a further integrated circuit 20 (IC 20) in accordance with the present subject matter. The integrated circuit 20 may be implemented in the form of CMOS circuits comprising digital and/or analog circuits. The integrated circuit 20 may comprise the first neuromorphic neuron apparatus 12, in the following also referred to as first NNA 12₁. Furthermore, the IC 20 may comprise further similar components of the IC 10, such as the crossbar array 700, the ADC 706, the second memory 707, the third memory 504, the configuration circuit 501 and the control unit 502. The configuration circuit 501 and the control unit 502 may be integrated in a configuration and control circuit 503. IC 20 may furthermore comprise a fourth memory 505 for storing incoming signals, for example the output values of the neuron of the previous layer of the network 30, such as out11(t), out12(t), . . . , out1p(t). In addition, the IC 10 may comprise a digital analog converter 506 for converting the digital incoming signals into the corresponding voltages v₁ . . . vₙ. In one example, the IC 10 may comprise an input communication channel 507 for transmitting the incoming signals from a bus system 509 to the fourth memory 505 and an output communication channel 508 for transmitting the output values out₁₋ₘ(t) to the bus system 509.

In addition to the first NNA 12, the IC 20 may comprise further neuromorphic neuron apparatuses 122_{2 . . . i . . . m}, in the following also referred to as further NNAs 12₂₋ₘ. The further NNAs 12₂₋ₘ may each be design similarly to the first NNA 12₁.

Hence, the further NNAs 12₂₋ₘ may each comprise an input and an accumulation block having a state variable for performing the inference task on the basis of the input data comprising the temporal sequence. Each further NNA 12₂₋ₘ may be switchable in a first and a second mode.

The accumulation block of the respective further NNA 12₂₋ₘ may be configured to perform an adjustment of the state variable of the respective accumulation block using the further current input signal x₂₋ₘ(t) of the respective further NNA 12₂₋ₘ and a decay function indicative of a decay behavior of the respective further NNA 12₂₋ₘ. The state variable of the respective accumulation block of the respective further NNA 12₂₋ₘ may be dependent on previously received one or more input signals of the respective further NNA 12₂₋ₘ.

The respective further NNA 12₂₋ₘ may be configured to receive the further current input signal x₂₋ₘ(t) of the respective further NNA 12₂₋ₘ via an input of the respective further NNA 12₂₋ₘ.

Furthermore, the respective further NNA 12₂₋ₘ may be configured to generate an intermediate value of the respective further NNA 12₂₋ₘ as a function of the state variable of the respective accumulation block if the respective further NNA 12₂₋ₘ is switched in the first mode.

Furthermore, the respective further NNA 12₂₋ₘ may be configured to generate the intermediate value of the respective further NNA 12₂₋ₘ as a function of the further current input signal x₂₋ₘ(t) of the respective further NNA 12₂₋ₘ and independently of the state variable of the respective accumulation block if the respective further NNA 12₂₋ₘ is switched in the second mode.

Furthermore, the respective further NNA 12₂₋ₘ may be configured to generate the respective further output value out₂₋ₘ(t) as a function of the intermediate value of the respective NNA 12₂₋ₘ.

Differently to the IC 10, the IC 20 may comprise single connections from each of the memory elements 707ᵢ of the second memory 707 to one of the inputs of the first NNA 12₁ or the further NNAs 12₂₋ₘ. By that, the current input signals xᵢ(t) and x₂₋ₘ(t) may be processed respectively by each of the first NNA 12₁ and the further NNA 12₁ for generating the corresponding output values out₁₋ₘ(t). Each of the output values out₂₋ₘ(t) may be generated by means of one respective further NNA of the further NNAs 12₂₋ₘ in the same way as the first NNA 12₁ generates the output value 18 on the basis of the first input signal x₁(t). Thus, the IC 20 may be configured to generate the output values out₁₋ₘ(t) in a parallel fashion. In one example, a number of the first NNA 12₁ and the further NNAs 12₂₋ₘ together may be smaller than the number of the column wires of the crossbar 700, for example be only a half or a quarter of the number of the column wires. Still, a parallel computation of a part of the output values out₁₋ₘ(t) may be possible, in this case. However, the size of the IC 20 may be reduced.

Each of the respective further output connections 705₁ may be coupled, i.e. electronically coupled, to one of the inputs of the further NNA 12₂₋ₘ via the ADC 706 and the second memory 707. In one example not shown in FIG. 9, the ADC 706 may forward each of the current input signals x₁(t) and x₂₋ₘ(t) directly to the respective input of one of the first NNA 12₁ and the further NNAs 12₂₋ₘ respectively without saving these signals in the second memory 707.

In the example shown in FIG. 9, the configuration circuit 501 may be configured to switch the first NNA 12₁ and the respective further NNAs 12₂₋ₘ simultaneously in the first mode or in the second mode.

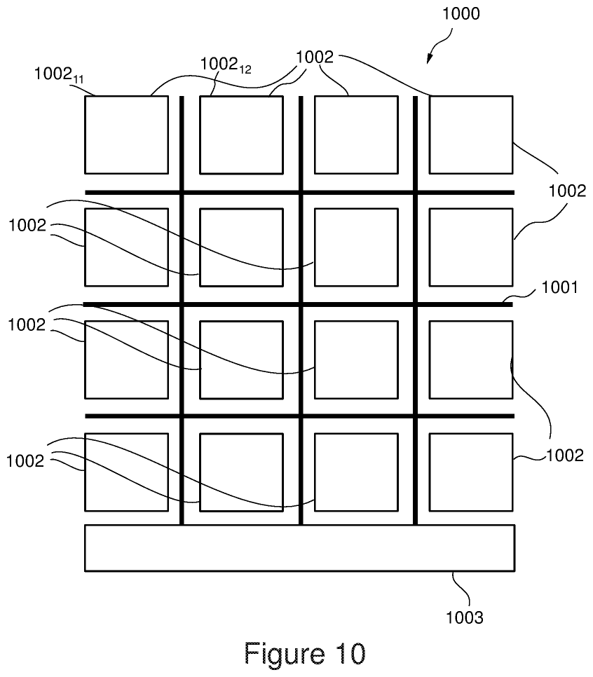

The IC 10 and the IC 20 may be both considered each as one type of core of a multi-core-chip architecture 1000 shown in FIG. 10. The architecture 1000 may comprise a communication bus 1001 and several cores 1002 for simulating the network 30. In one example, the network 30 may comprise several hidden layers, for example up to five, ten, hundred or hundreds of hidden layers, the network 30 being a deep neural network. Each core of the cores 1002 may be used to simulate one hidden layer of the network 30.

Each core of the cores 1002 may be designed like the IC 10 in one example. In a further example, each core of the cores 1002 may be designed like the IC 20. The communication bus 1001 may provide a communication channel for transmitting the output values out₁₋ₘ(t) generated by one of the cores 1002 to another core of the cores 1002.

In the following a transmission of signals between two cores of the cores 1002, between a first core 1002₁₁ and a second core 1002₁₂, for simulating a propagation of signals from the previous layer to the actual layer of the network 30 may be described. Each core 1002₁₁,1002₁₂ may comprise the above mentioned input voltages v₁ . . . vₙ as current input core signals x_core₁₋ₘ(t) and the above mentioned output values out₁₋ₘ(t) as current output core signals out_core₁₋ₘ(t). The output values out₁₋ₘ(t) may be generated in the form of output voltages v₁ . . . vₘ. Here, binary signals may be generated by the output voltages v₁ . . . vₘ. For example, a pulse width modulation scheme may be applied to generate the output voltages v₁ . . . vₘ. In another example, analog signal generation may comprise generating the output voltages v₁ . . . vₘ.

The first core 1002₁₁ may send the output voltages v₁ . . . vₘ of the first core 1002₁₁ via the output channel 508 of the first core 1002₁₁ to the bus 1001. The second core 1002₁₂ may receive the output voltages v₁ . . . vₘ of the first core 1002₁₁ via the bus 1001 and the input channel 507 of the second core 1002₁₂ in the form of the input voltages v₁ . . . vₙ of the second core 1002₁₂. In this case, the number m of the output voltages v₁ . . . vₘ of the first core 1002₁₁ may be equal to the number n of the input voltages v₁ . . . vₙ of the second core 1002₁₂, i.e. m=n. Though, this must not necessary be the case in every application of the architecture 1000.

In one example, the number m of the output voltages v₁ . . . vₘ of the first core 1002₁₁ may be less than the number n of the input voltages v₁ . . . vₙ of the second core 1002₁₂, i.e. m<=n. In this case, a value of the input voltages vₘ₋ₙ . . . vₙ of the second core 1002₁₂ may be zero. The input channel 507 may, for example, assign a value of zero to each of the input voltages vₘ₋ₙ . . . vₙ, in this case. In this case, the row wires 703_{m-n . . . n} may not generate single electric currents in the memristors 701_{1-m, (m-n)-n} of the second core 1002₁₂. Thus, the crossbar 700 enables to change a number of hidden layers of the network 30 to be simulated without changing hardware elements of the architecture 1000.

In one example, the first NNA 12 of at least one core of the cores 1002, for example the first NNA 12 and/or the further NNAs 12₂₋ₘ of the first core 1002₁₁, is switched in the first mode and the first NNA 12 of at least one of the other cores of the cores 1002, for example the first NNA 12 and/or the further NNAs 12₂₋ₘ of the second core 1002₁₂, is switched in the second mode. For example, the NNAs 12₁₋ₘ of the first core 1002₁₁ may be switched in the second mode to simulate the first hidden layer 32, the first hidden layer 32 comprising neurons such as neurons of an MLP-network. In addition, the NNAs 12₁₋ₘ of the second core 1002₁₂ may be switched in the first mode to simulate the second hidden layer 33, the second hidden layer 33 comprising spiking neurons. The architecture shown in FIG. 10 may, for example, be used to simulate sixteen hidden layers of the network 30. For simplicity, in FIG. 3 only two hidden layers of the network 30 are shown. In one example, a single core of the cores 1002 may be configured to simulate two or more hidden layers of the network 30.

The architecture 1000 may comprise the global processor 1003 to configure each of the cores 1002. The processor 1003 may be configured to send corresponding configuration messages via the bus 1001 to the respective the cores 1002 to be configured. The configuration messages may be read by the corresponding configuration and control circuit 503 of the respective cores 1002 to be configured. Upon receiving the respective configuration message, the respective configuration and control circuit 503 may switch the NNAs 12₁₋ₘ of the corresponding core of the cores 1002 to be configured either into the first or the second mode, dependent on a content of the configuration message.

The global processor 1003 may be considered as a control circuit. The global processor 1003 may comprise a timer to synchronize the cores 1002. In one example, the first core 1002₁₁ may be clocked with a first time step size and the second core 1002₁₂ may be clocked with a second time step size, the first time step size being an integer multiple of the second time step size.

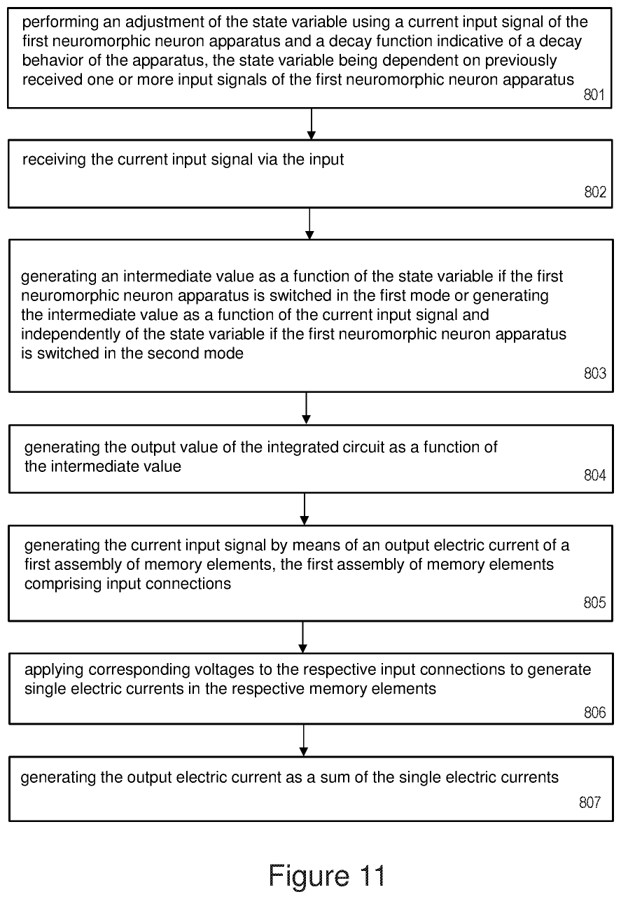

FIG. 11 is a flowchart of a method for generating the output value 18 of the IC 10. In step 801, an adjustment of the state variable 15 using the current input signal x(t) of the first neuromorphic neuron apparatus 12 and the decay function indicative of a decay behavior of the apparatus 12 may be performed. In step 802, the current input signal x(t) may be received via the input 13. In step 803, the intermediate value 16 may be generated as a function of the state variable 15 if the first neuromorphic neuron apparatus 12 is switched in the first mode. The intermediate value 16 may be generated as a function of the current input signal x(t) and independently of the state variable 15 if the first neuromorphic neuron apparatus 12 is switched in the second mode. In step 804, the output value 18 of the integrated circuit 10 may be generated as a function of the intermediate value 16.

The method may further comprise further steps 805, 806, 807. In step 805, the current input signal x(t) may be generated by means of the first output electric current of the first assembly 704 of the memristors. In step 806, the corresponding voltages v₁ . . . vₙ may be applied to the respective input connections 703₁, 703₂ . . . 703ₙ to generate the single electric currents I₁₁, I₁₂ . . . I₁ₙ in the respective memristors 701i, 701₁₂ . . . 701ᵢₙ. In step 807, the first output electric current Iᵢ may be generated as a sum of the single electric currents I₁₁, I₁₂ . . . I₁ₙ.

In one example, a value of the conductance of each RME 701ᵢⱼ may be in a drifted, for example in a decayed, state after a given period of time ΔT has passed after programming the respective RME 701ᵢⱼ. The drifted state of the conductance of each RME 701ᵢⱼ may be approximately equal to a respective target state of the conductance of each RME 701ᵢⱼ which may be the value Gᵢⱼ of each conductance mentioned above. For example, a value of the conductance of each RME 701ᵢⱼ in the decayed state may deviate from the respective target state of the conductance Gᵢⱼ of each RME 701ᵢⱼ less than ten percent. According to a further example, the value of the conductance of each RME 701ᵢⱼ in the decayed state may deviate from the respective target state of the conductance Gᵢⱼ of each RME 701ᵢⱼ less than one percent. The given period of time ΔT may be dependent on a point of time when the RMEs 701 are used.

The respective RME 701ᵢⱼ may be configured for setting the respective conductance of the RME 701ᵢⱼ to a respective initial state G_{ij_init} and to comprise a respective drift of the respective conductance of the RME 701ᵢⱼ from the respective initial state G_{ij_init} to the respective drifted state. The respective initial state of the respective conductance G_{ij_init} may be computable by a processor by means of a respective initialization function. The respective initialization function may be different for each RME 701ᵢⱼ in one example. In another example, the respective initialization function may be the same for each RME 701ᵢⱼ, for example the initialization function 200 shown in FIG. 12.

The initialization function 200 may map each target state of the conductance Gᵢⱼ of each RME 701ᵢⱼ, in the FIG. 12 depicted as G_{target_i}, to a respective initial value of the conductance of each RME 701ᵢⱼ, in the FIG. 12 depicted as G_{init_i}. The initialization function 200 may be a polynomial gained by experiments performed with the RMEs 701, especially with each RME 701ᵢⱼ.

The processor may be an external processor or may the global processor 1003. The processor may store the parameters or coefficients of the initialization function 200 in order to compute the respective initial state G_{ij_init} of each RME 701ᵢⱼ on the basis of the respective target state of the conductance Gᵢⱼ of each RME 701ᵢⱼ.

A set-up-method for setting up each RME 701ᵢⱼ for operation may comprise measuring an elapsed time from an initial point of time of programming the conductance to the computed initial state of the conductance to an actual point of time. Furthermore, the set-up-method may comprise comparing the measured elapsed time with the given period of time ΔT. The given period of time ΔT may depend on a usage of each RME 701ᵢⱼ, for example on a point of time of a usage of the crossbar array 700 as a whole. The set-up-method may comprise releasing the crossbar array 700 for operation if the measured elapsed time is greater than the given period of time ΔT.

For example, the voltages v₁₋ₙ may not be applied to the input connections 703₁, 703₂ . . . 703ₙ till the elapsed time is greater than the given period of time ΔT. Or, in other words, the voltages v₁₋ₙ may be applied to the input connections 703₁, 703₂ . . . 703ₙ if the elapsed time is greater than the given period of time ΔT. In one example, the voltages vₙ may be applied to the input connections 703₁, 703₂ . . . 703ₙ only if the elapsed time is greater than the given period of time ΔT.

In most cases, the given period of time ΔT may be chosen such that a further decay of the conductance over time after the given period of time ΔT has passed may be low compared to a decay of the conductance over time directly after programming each RME 701ᵢⱼ to the initial state.

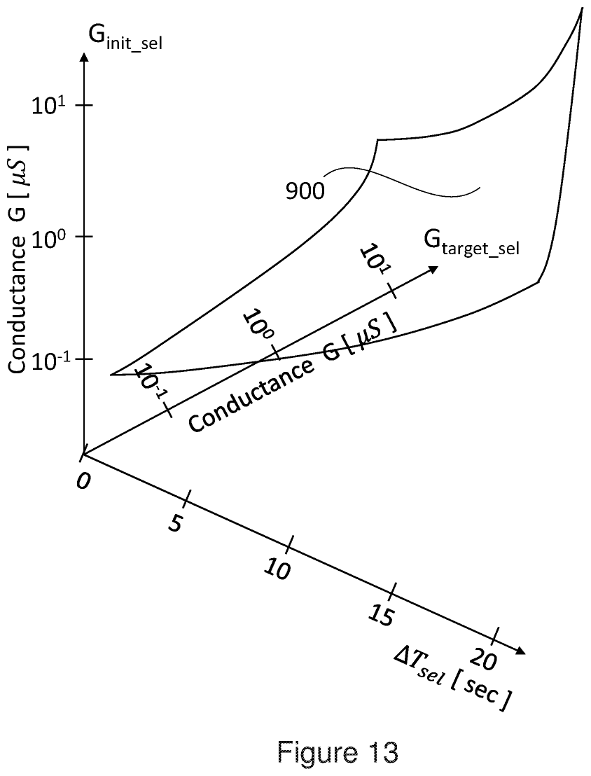

In one example, the respective initial state G_{ij_init} of the conductance of each RME 701ᵢⱼ, depicted as G_{init_sel} in FIG. 13, may be computed on the basis of the respective target state of the conductance Gᵢⱼ of each RME 701ᵢⱼ, depicted as G_{target_sel} in FIG. 13, and a respective selected point of time of operation ΔTₛₑₜ of each RME 701ᵢⱼ on the basis of a global initialization function 900 shown in FIG. 13. The respective selected points of time of operation of each RME 701ᵢⱼ may be equal in one example. In another example, the respective selected points of time of operation of each RME 701ᵢⱼ may differ from each other. This may be practical, if each respective point of time of operation of each RME 701ᵢⱼ may be known in advance.

For example, the second core 1002₁₂ may be configured to simulate the second hidden layer 33 and the first core 1002₁₁ may be configured to simulate a previous layer, for example the first hidden layer 32. As a simulation of the network 30 may start with a simulation of the first hidden layer 32 and may progress with a simulation of the second hidden layer 33, a first point of time of usage of the first core may be earlier than a second point of time of usage of the second core. Therefore, in one example, the respective conductance of the RME 701ᵢⱼ of the first core may be set to the respective initial state G_{ij_init} of the conductance such that each respective conductance of the RME 701ᵢⱼ of the first core may reach its respective target state of the conductance Gᵢⱼ earlier than each of the respective conductance of the RME 701ᵢⱼ of the second core may reach its respective target state of the conductance Gᵢⱼ.

Programming the conductance of the RMEs 701, preferably of each RME 701ᵢⱼ, to the computed respective initial state of the conductance of the RMEs may enable a more accurate calculation of the current input signal of the first NNA 2, 12. If the first NNA 2, 12 is switched in the first mode this may increase the accuracy of the first NNA 2, 12 as the output value 18 is dependent on a development over time of the state variable 15. If a change over time of the RME 701ᵢⱼ is lower the output value 18 may be calculated more accurately. This may be also advantageous if one of the cores 1002 is switched in the first mode and another one of the cores 1002 is switched in the second mode. For example, if results calculated with the core being switched in the first mode may be compared with results calculated with the core being switched in the second mode.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

1. An integrated circuit comprising a first neuromorphic neuron apparatus, the first neuromorphic neuron apparatus comprising an input and an accumulation block having a state variable for performing an inference task on the basis of input data comprising a temporal sequence, the first neuromorphic neuron apparatus being switchable in a first mode and in a second mode;
the accumulation block being configured to
perform an adjustment of the state variable using a current input signal of the first neuromorphic neuron apparatus and a decay function indicative of a decay behavior of the apparatus, the state variable being dependent on previously received one or more input signals of the first neuromorphic neuron apparatus;
the first neuromorphic neuron apparatus being configured to
receive the current input signal via the input;
generate an intermediate value as a function of the state variable if the first neuromorphic neuron apparatus is switched in the first mode;
generate the intermediate value as a function of the current input signal and independently of the state variable if the first neuromorphic neuron apparatus is switched in the second mode; and
generate an output value as a function of the intermediate value.

2. The integrated circuit of claim 1, the integrated circuit further comprising a first assembly of memory elements, the first assembly of memory elements comprising input connections for applying corresponding voltages to the respective input connections to generate single electric currents in the respective memory elements and at least one output connection for outputting an output electric current, the memory elements being connected to each other such that the output electric current is a sum of the single electric currents, the output connection of the first assembly being coupled to the input of the first neuromorphic neuron apparatus, wherein the integrated circuit is configured to generate the current input signal on the basis of the output electric current.

3. The integrated circuit of claim 2, the integrated circuit further comprising further assemblies of memory elements, the further assemblies of the memory elements each being connected to the input connections of the first assembly for applying the corresponding voltages to the memory elements of each of the further assemblies to generate respective further single electric currents in the respective memory elements of each of the further assemblies, each of the further assemblies comprising a respective further output connection for outputting a respective further output electric current, the memory elements of each of the further assemblies being connected to each other such that the respective further output electric current is a respective sum of the respective further single electric currents in the memory elements of the respective assembly, wherein the integrated circuit is configured to generate respective further current input signals of the first neuromorphic neuron apparatus or of further neuromorphic neuron apparatuses of the integrated circuit each on the basis of the respective further output electric current and to generate further output values each on the basis of the respective further current input signal by means of the first neuromorphic neuron apparatus or the further neuromorphic neuron apparatuses.

4. The integrated circuit of claim 2, wherein the memory elements are resistive memory elements.

5. The integrated circuit of claim 3, the integrated circuit further comprising an analog digital converter and a first memory, the analog digital converter being configured to convert the output electric current into the current input signal and the further output electric currents into the respective further current input signals of the first neuromorphic neuron apparatus, the first memory being configured to store the current input signal and the further current input signals, and the integrated circuit being configured to generate the further output values each on the basis of the respective further current input signal by means of the first neuromorphic neuron apparatus.

6. The integrated circuit of claim 3, the integrated circuit further comprising a neuromorphic neuron apparatuses, the further neuromorphic neuron apparatuses comprising each an input and an accumulation block having a state variable for performing the inference task on the basis of the input data comprising the temporal sequence, each further neuromorphic neuron apparatus being switchable in a first and a second mode and each of the respective further output connections of the further assemblies being coupled to one of the inputs of the further neuromorphic neuron apparatuses;
the accumulation block of the respective further neuromorphic neuron apparatus being configured to
perform an adjustment of the state variable of the respective accumulation block using the further current input signal of the respective further neuromorphic neuron apparatus and a decay function indicative of a decay behavior of the respective apparatus, the state variable of the respective accumulation block being dependent on previously received one or more input signals of the respective further neuromorphic neuron apparatus;
the respective further neuromorphic neuron apparatus being configured to
receive the further current input signal of the respective further neuromorphic neuron apparatus via the input of the respective further neuromorphic neuron apparatus;
generate an intermediate value of the respective further neuromorphic neuron apparatus as a function of the state variable of the respective accumulation block if the respective further neuromorphic neuron apparatus is switched in the first mode;
generate the intermediate value of the respective further neuromorphic neuron apparatus as a function of the further current input signal of the respective further neuromorphic neuron apparatus and independently of the state variable of the respective accumulation block if the respective further neuromorphic neuron apparatus is switched in the second mode; and
generate the respective further output value as a function of the intermediate value of the respective neuromorphic neuron apparatus.

7. The apparatus of claim 3, the memory elements of the first assembly and the memory elements of the further assemblies being arranged in rows and columns, the memory elements each representing an entry of a matrix, the entries of the matrix representing a respective weight of a connection between two neurons of an artificial neural network.

8. The integrated circuit of claim 2, the integrated circuit further comprising an analog digital converter, the output connection of the first assembly of the memory elements being coupled to the input of the first neuromorphic neuron apparatus via the analog digital converter, wherein the output connection of the first assembly is coupled to an input connection of the analog digital converter and an output connection of the analog digital converter is coupled to the input of the first neuromorphic neuron apparatus and the analog digital converter is configured to convert the output electric current into the current input signal, wherein the current input signal is a digital signal.

9. The integrated circuit of claim 1, the integrated circuit further comprising a first switchable circuit being configured to run in a first mode or in a second mode and
to generate the intermediate value as a function of the state variable if the first switchable circuit is switched in the first mode; and
to generate the intermediate value as a function of the current input signal and independently of the state variable if the first switchable circuit is switched in the second mode.

10. The integrated circuit of claim 9, wherein the first switchable circuit is configured to generate the intermediate value as a function of the current input signal and parameter values derived from a batch normalization algorithm of a training data set for training the first neuromorphic neuron apparatus if the first switchable circuit is switched in the second mode.

11. The integrated circuit of claim 9, the integrated circuit further comprising a second switchable circuit and a configuration circuit, the second switchable circuit being configured to run in a first mode or in a second mode and to generate the output value according to a first activation function on the basis of the intermediate value if the second switchable circuit is switched in the first mode and to generate the output value according to a second activation function on the basis of the intermediate value if the second switchable circuit is switched in the second mode, the configuration circuit being configured to switch the first switchable circuit and the second switchable circuit in the first mode or the second mode.

12. The integrated circuit of claim 6, further comprising a configuration circuit, the configuration circuit being configured to switch the first neuromorphic neuron apparatus and the respective further neuromorphic neuron apparatuses simultaneously in the first mode or in the second mode.

13. The integrated circuit of claim 6, further comprising a rectified linear unit, the rectified linear unit being configured to generate a further intermediate value as a function of the intermediate value independently if the first neuromorphic neuron apparatus is switched in the first mode or if the first neuromorphic neuron apparatus is switched in the second mode, the first neuromorphic neuron apparatus being configured to generate the output value on the basis of the further intermediate value.

14. The integrated circuit of claim 6, further comprising a comparison circuit, the comparison circuit being configured to compare the further intermediate value with a threshold value if the first neuromorphic neuron apparatus is switched in the first mode, the first neuromorphic neuron apparatus being configured to set the output value equal to one if the further intermediate value is greater than the threshold value and to set the output value equal to zero if the further intermediate value is less than or equal to the threshold value.

15. The integrated circuit of claim 5, further comprising an input conversion circuit, the input conversion circuit being configured to scale the current input signal using a scaling, the scaling being dependent on a range of output values of the analog digital converter and independent from a mode of the first neuromorphic neuron apparatus.

16. The integrated circuit of claim 1, the first neuromorphic neuron apparatus being configured to generate the output value such that a range of admissible values of the output value is independent of a mode of the first neuromorphic neuron apparatus.

17. The integrated circuit of claim 1, further comprising an accumulation block comprises a memory element, the memory element comprising a changeable physical quantity for storing the state variable, the physical quantity being in a drifted state, the memory element being configured for setting the physical quantity to an initial state, wherein the memory element comprises a drift of the physical quantity from the initial state to the drifted state, wherein the initial state of the physical quantity is computable by means of an initialization function, wherein the initialization function is dependent on a target state of the physical quantity and the target state of the physical quantity is approximately equal to the drifted state of the physical quantity and is dependent on the state variable.

18. The integrated circuit of claim 2, wherein each resistive memory element comprises a respective changeable conductance, the respective conductance being in a respective drifted state, the respective resistive memory element being configured for setting the respective conductance to a respective initial state, wherein the respected resistive memory element comprises a respective drift of the respective conductance from the respective initial state to the respective drifted state and the respective initial state of the respective conductance is computable by means of a respective initialization function, wherein the respective initialization function is dependent on a respective target state of the respective conductance and the respective target state of the respective conductance is approximately equal to the respective drifted state of the respective conductance.

19. A multi-core-chip architecture, the architecture comprising integrated circuits as cores, each integrated circuit comprising a first neuromorphic neuron apparatus, the first neuromorphic neuron apparatus comprising an input and an accumulation block having a state variable for performing an inference task on the basis of input data comprising a temporal sequence, the first neuromorphic neuron apparatus being switchable in a first mode and in a second mode;
the accumulation block being configured to
perform an adjustment of the state variable using a current input signal of the first neuromorphic neuron apparatus and a decay function indicative of a decay behavior of the apparatus, the state variable being dependent on previously received one or more input signals of the first neuromorphic neuron apparatus;
the first neuromorphic neuron apparatus being configured to
receive the current input signal via the input;
generate an intermediate value as a function of the state variable if the first neuromorphic neuron apparatus is switched in the first mode;
generate the intermediate value as a function of the current input signal and independently of the state variable if the first neuromorphic neuron apparatus is switched in the second mode; and
generate an output value as a function of the intermediate value.

20. The multi-core-chip architecture of claim 19, each integrated circuit further comprising a respective first assembly of memory elements, the respective first assembly of memory elements comprising input connections for applying corresponding voltages to the respective input connections to generate single electric currents in the respective memory elements and at least one output connection for outputting a corresponding output electric current of the respective first assembly, the memory elements being connected to each other such that the output electric current is a sum of the single electric currents, the output connection of the respective first assembly being coupled to the input of the first neuromorphic neuron apparatus of the respective integrated circuit, wherein each integrated circuit is configured to generate the current input signal of the first neuromorphic neuron apparatus of the respective integrated circuit on the basis of the respective output electric current, wherein at least two of the integrated circuits are connected to each other to simulate a neural network comprising at least two hidden layers.

21. The multi-core-chip architecture of claim 19, wherein the first neuromorphic neuron apparatus of at least one of the integrated circuits is switched in the first mode and the first neuromorphic neuron apparatus of at least one of the other integrated circuits is switched in the second mode.

22. The multi-core-chip architecture of claim 19, the integrated circuits being controlled by a control circuit, the control circuit comprising a timer to synchronize the integrated circuits.

23. The multi-core-chip architecture of claim 19, wherein a first integrated circuit of the integrated circuits is clocked with a first time step size and the first neuromorphic neuron apparatus of the first integrated circuit is switched in the first mode and a second integrated circuit of the integrated circuits is clocked with a second time step size and the first neuromorphic neuron apparatus of the second integrated circuit is switched in the second mode, the second time step size being an integer multiple of the first time step size.

24. A method for generating an output value of an integrated circuit, the integrated circuit comprising a first neuromorphic neuron apparatus, the first neuromorphic neuron apparatus comprising an input and an accumulation block having a state variable for performing an inference task on the basis of input data comprising a temporal sequence, the first neuromorphic neuron apparatus being switchable in a first mode and in a second mode, the method comprising;
performing an adjustment of the state variable using a current input signal of the first neuromorphic neuron apparatus and a decay function indicative of a decay behavior of the apparatus, the state variable being dependent on previously received one or more input signals of the first neuromorphic neuron apparatus;
receiving the current input signal via the input;
generating an intermediate value as a function of the state variable if the first neuromorphic neuron apparatus is switched in the first mode or generating the intermediate value as a function of the current input signal and independently of the state variable if the first neuromorphic neuron apparatus is switched in the second mode; and
generating the output value of the integrated circuit as a function of the intermediate value.

25. The method of claim 24, the method further comprising
generating the current input signal by means of an output electric current of a first assembly of memory elements, the first assembly of memory elements comprising input connections;
applying corresponding voltages to the respective input connections to generate single electric currents in the respective memory elements;
generating the output electric current as a sum of the single electric currents.

26. A computer program product comprising a computer-readable storage medium having computer-readable program code embodied therewith, the computer-readable program code configured to:
generate an output value of an integrated circuit, the integrated circuit comprising a first neuromorphic neuron apparatus, the first neuromorphic neuron apparatus comprising an input and an accumulation block having a state variable for performing an inference task on the basis of input data comprising a temporal sequence, the first neuromorphic neuron apparatus being switchable in a first mode and in a second mode, the method comprising;
performing an adjustment of the state variable using a current input signal of the first neuromorphic neuron apparatus and a decay function indicative of a decay behavior of the apparatus, the state variable being dependent on previously received one or more input signals of the first neuromorphic neuron apparatus;
receiving the current input signal via the input;
generating an intermediate value as a function of the state variable if the first neuromorphic neuron apparatus is switched in the first mode or generating the intermediate value as a function of the current input signal and independently of the state variable if the first neuromorphic neuron apparatus is switched in the second mode; and
generating the output value of the integrated circuit as a function of the intermediate value.
